(19) United States
(12) Patent Application Publication
(10) Pub. No.: US 2005/0012429 A1
(43) Pub. Date: Jan. 20, 2005

(54) Piezoelectric body manufacturing method, piezoelectric body, ultrasonic probe, ultrasonic diagnosing device, and nondestructive inspection device

(76) Inventors: Toshiharu Sato, Kanagawa (JP); Kiyohide Amemiya, Kanagawa (JP); Yoshiyuki Sugiyama, Kanagawa (JP)

Correspondence Address: PEARNE & GORDON LLP, 1801 EAST 9TH STREET, SUITE 1200, CLEVELAND, OH, 44114-3108, US

(21) Appl. No.: 10/496,241

(22) PCT Filed: Nov. 21, 2002
(86) PCT No.: PCT/JP02/12143

(30) Foreign Application Priority Data
Nov. 22, 2001 (JP) 2001-357398

(51) Int. Cl. H01L 41/04

(52) U.S. Cl. 310/311

(57) ABSTRACT

Herein disclosed are a piezoelectric device, an ultrasonic probe, an ultrasonic diagnostic apparatus, a nondestructive testing device, and a method of producing one or more piezoelectric devices respectively having predetermined thickness distributions equal in shape to one another with high precision to realize an ultrasound diagnosis with high reliability. The method of producing one or more piezoelectric devices comprises a molding process of: molding a mixture of raw materials including piezoelectric ceramic powders and a binding agent immersed in a solvent to form a plurality of sheet-like raw material elements 6 each having a thickness in a range of a few ten microns to a few hundred microns by way of, for example, a Doctor Blade technique, a laminating process of laminating a plurality of sheet-like raw material elements 6 to obtain a piezoelectric element 7, a pressing process of imparting pressing forces to the piezoelectric element 7 to obtain a piezoelectric element 7a having a predetermined shape, and a burning process of burning the piezoelectric element 7a.

### TECHNICAL FIELD

The present invention relates to a method of producing a piezoelectric device available for diagnosis, treatment, nondestructive testing, or the like, and more particularly to a piezoelectric device, an ultrasonic probe, an ultrasonic diagnostic apparatus, and a nondestructive testing device.

### BACKGROUND ART

The conventional ultrasonic probe of this type is shown in FIG. 24 as comprising a piezoelectric device 1 having a thickness concavely curved in a manner that the thickness of the piezoelectric device 1 gradually increases from a center portion toward end portions along the minor axis, an acoustic matching layer 2 having a thickness concavely curved in accordance with that of the piezoelectric device 1 with a result that the thickness of the acoustic matching layer 2 gradually increases from a center portion toward end portions along the minor axis to ensure that an ultrasonic wave is efficiently transmitted and received, an acoustic lens 3 for converging the ultrasonic wave on one fixed focal point with respect to the minor direction, and a rearward load 4, placed rearward of the piezoelectric device 1, for carrying out an acoustic damping operation. The ultrasonic wave emitted from the piezoelectric device 1 varies in frequency spectrum in accordance with the thickness of the piezoelectric device 1 resulting in the fact that the frequency spectrum of the ultrasonic wave tends to shift to a higher frequency range as the thickness of the piezoelectric device 1 decreases (as disclosed in Japanese Patent Laid-Open Publication No. 58-29455).

The above-mentioned piezoelectric device 1 having a thickness gradually varied along the minor axis is operative to vibrate at a frequency gradually varied in accordance with the thickness of the piezoelectric device 1 in a manner that the frequency of the vibration of the piezoelectric device 1 gradually decreases from the center portion toward the end portions along the minor axis. Furthermore, the effective aperture of the piezoelectric device 1 is gradually varied in accordance with the thickness of the piezoelectric device 1 in a manner that the effective aperture of the piezoelectric device 1 gradually increases from the center portion where the piezoelectric device 1 vibrates at a high frequency toward the end portions where the piezoelectric device 1 vibrates at a frequency lower than that of the center portion. Accordingly, an ultrasonic diagnostic apparatus such as for example a nondestructive testing device equipped with the piezoelectric device as shown in FIG. 24 can generate a thin ultrasound beam at a short focal distance in the case that high frequency components of the ultrasonic wave are extracted, and generate a thin ultrasound beam at a long focal distance in the case that low frequency components of the ultrasonic wave are extracted. This leads to the fact that the ultrasonic diagnostic apparatus equipped with the piezoelectric device as shown in FIG. 24 can generate thin ultrasound beams from a short distance to a long distance by stepwise changing the frequency components of the ultrasonic wave to be extracted, thereby improving its azimuth resolution.

One method of producing a piezoelectric device of this type comprises the step of carrying out a grinding processing on materials of the piezoelectric device with a disc-shaped grinding wheel 5 as shown in FIG. 25 (as disclosed in Japanese Patent Laid-Open Publication No. 07-107595). The grinding wheel 5 has a width equal to that of the piezoelectric device 1 and has such a shape that the piezoelectric device 1 with a desired thickness distribution can be ground as a result of the grinding processing. The grinding wheel 5 is designed to move along a Y-axis direction to grind the materials while rotating around a rotation axis parallel to an X-axis parallel to a plane bottom surface of the piezoelectric device 1.

Another method of producing a piezoelectric device of this type comprises the steps of rotating the grinding wheel 5 around a rotation axis inclined to the X-axis in a manner that an edge of the grinding wheel 5 is held in contact with the surface of the piezoelectric device 1 as shown in FIG. 26, and repeatedly grinding the material with the edge of the grinding wheel 5 while the grinding wheel 5 is moving between two end portions of the piezoelectric device 1 along the X-axis. The position of the grinding wheel 5 is controlled with respect to a Z-axis direction so that the piezoelectric device 1 having a desired thickness distribution can be ground as a result of the grinding processing (as disclosed in Japanese Patent Laid-Open Publication No. 07-107595). The grinding wheel 5 is designed to repeatedly move along the Y-axis direction while caring out the above-mentioned grinding processing on the materials with a result that the piezoelectric device 1 is thus ground along the Y-axis.

The conventional ultrasonic probe as previously mentioned, however, encounters a drawback that the piezoelectric device is quite easy to be cracked by the reason that the thickness of the piezoelectric device is required to be several hundred μm in the case that the conventional ultrasonic probe is for use in, for example, an ultrasonic diagnostic apparatus, and the piezoelectric device is designed to emit an ultrasonic wave of several MHz, and made of a ground piezoelectric ceramic such as for example PZT (lead zirconate titanate).

The conventional ultrasonic probe encounters another drawback that a distance between electrodes respectively placed on a first surface of the piezoelectric device and a second surface of the piezoelectric device opposite to the first surface of the piezoelectric device across the thickness of the piezoelectric device tends to be uneven by the reason that the thickness of the piezoelectric device constituting the conventional ultrasonic probe is uneven. The unevenness of the distance between the electrodes causes electric field strength and thus polarization state to be uneven in the event that a power voltage is applied to the piezoelectric device to polarize the piezoelectric device. The fact that an electric field applied to the thin center portion is greater than an electric field applied to the end portion while the piezoelectric device is polarized leads to the fact that the piezoelectric device is caused to be distorted, thereby making it easier for the piezoelectric device to be cracked while the piezoelectric device is polarized. Furthermore, the fact that the electric field applied to the thin center portion is greater than the electric field applied to the end portion while the piezoelectric device is driven leads to the fact that the piezoelectric device is caused to be distorted, thereby making it easier for the piezoelectric device to be cracked while the conventional ultrasonic probe is driven.

The conventional method of producing a piezoelectric device encounters a drawback that a thin portion of the piezoelectric device is difficult to be ground by the reason that the conventional method comprises the step of carrying out a grinding processing on materials of the piezoelectric device. As the ultrasonic diagnostic apparatus is required to emit an ultrasonic wave of a higher frequency such as, for example, several dozen MHz, it becomes more difficult to grind the thin portion of the piezoelectric device. Furthermore, in the case that the width of the piezoelectric device is required to be uneven in addition to the thickness of the piezoelectric device, the end portions of the piezoelectric device are required to be ground accordingly. Assuming that the thickness of the piezoelectric device is several hundred μm at the end portion, a grinding tool such as, for example, a grinding wheel 5 is required to be minute in size equal to or less than several hundred μm, and it is extremely difficult to carry out a grinding processing on materials of the piezoelectric device. It is also extremely difficult to constantly produce a plurality of piezoelectric devices equal in shape to one another with high precision.

The present invention is made for the purpose of overcoming the above-mentioned conventional drawbacks and is directed to a method of producing a plurality of piezoelectric devices having a thickness distribution equal in shape to one another with high precision, and more particularly to an ultrasonic probe, an ultrasonic diagnostic apparatus, and a nondestructive testing device.

### DISCLOSURE OF INVENTION

In accordance with the present invention, there is provided a method of producing a piezoelectric device, comprising the steps of: (a) molding one or more raw material elements including at least one piezoelectric material to form a predetermined piezoelectric element; and (b) imparting pressing forces to the piezoelectric element to have the piezoelectric element molded into a predetermined shape. The method makes it possible for a manufacturer to produce a piezoelectric device having a predetermined uneven thickness distribution with ease, while eliminating the need of carrying out any technically-difficult minute machining processing such as for example a grinding processing. Furthermore, a plurality of piezoelectric devices equal in shape to one another can be constantly produced with high precision resulting from the fact that the shape of a die is simply transferred to them.

In the aforementioned method of producing a piezoelectric device, the step (a) may have a step of laminating a plurality of sheet-like raw material elements respectively having thicknesses collectively in accordance with a thickness distribution of the piezoelectric device. The method makes it possible for a manufacturer to produce a piezoelectric device having a desired thickness distribution with increased flexibility.

In the aforementioned method of producing a piezoelectric device, the step (a) may have a step of laminating the number and shapes of sheet-like raw material elements in accordance with a thickness distribution of the piezoelectric device. The method makes it possible for a manufacturer to produce a piezoelectric device having desired shape and thickness distribution with increased flexibility.

In the aforementioned method of producing a piezoelectric device, the step (a) may have a step of laminating one or more sheet-like raw material elements respectively having widths collectively in accordance with a thickness distribution of the piezoelectric device. The method makes it possible for a manufacturer to produce a piezoelectric device having desired shape and width distribution with increased flexibility. Preferably, one or more sheet-like raw material elements respectively formed with through bores should be laminated. More preferably, one or more sheet-like raw material elements should be laminated in a manner that the through bores of the one or more sheet-like raw material elements in size collectively corresponds to a thickness distribution of the piezoelectric device.

In accordance with the present invention, there is provided a method of producing a piezoelectric device, comprising the steps of: (c) producing a first piezoelectric body having a non-plane first surface and a plane second surface opposite to the first surface, and a second piezoelectric body having a plane first surface and a plane second surface opposite to the first surface, the second piezoelectric body having electrodes respectively on the first and second surfaces; and (d) fixedly connecting the first piezoelectric body to the second piezoelectric body with the second surface of the first piezoelectric body held in contact with the first surface of the second piezoelectric body. The method makes it possible for a manufacturer to produce a piezoelectric device, in which an electric field strength applied to the piezoelectric device maintains constant. This leads to the fact that the polarization state of the piezoelectric device maintains constant as well as the piezoelectric device is kept from being excessively distorted so that the piezoelectric device is not cracked.

In accordance with the present invention, there is provided a piezoelectric device comprising a piezoelectric element having one or more raw material elements including a piezoelectric material, in which pressing forces have been imparted to the piezoelectric element to have the piezoelectric element molded. The present invention makes it possible for a manufacturer to produce a piezoelectric device having a predetermined uneven thickness distribution with ease, while eliminating the need of carrying out any technically-difficult minute machining processing such as for example a grinding processing. Furthermore, a plurality of piezoelectric devices equal in shape to one another can be constantly produced with high precision because of the fact that the shape of the die is simply transferred to them.

In the aforementioned piezoelectric device, the piezoelectric element may have a plurality of sheet-like raw material elements respectively having thicknesses and laminated in accordance with a thickness distribution of the piezoelectric device. The present invention makes it possible for a manufacturer to produce a piezoelectric device having a desired thickness distribution with increased flexibility by adaptively laminating a plurality of sheet-like raw material elements respectively having thicknesses collectively in accordance with the thickness distribution of the piezoelectric device.

In the aforementioned piezoelectric device, the piezoelectric element may have a plurality of sheet-like raw material elements respectively having thicknesses and formed with through bores, and laminated in accordance with a thickness distribution of the piezoelectric device. The present invention makes it possible for a manufacturer to produce a piezoelectric device having shape and desired thickness distributions with increased flexibility.

In the aforementioned piezoelectric device, the piezoelectric element may have a sheet-like raw material element formed with a through bore in size in accordance with a thickness distribution of the piezoelectric device. The present invention makes it possible for a manufacturer to produce a piezoelectric device having desired shape and width distribution with increased flexibility. Preferably, one or more sheet-like raw material elements should be laminated in a manner that the through bores of the one or more sheet-like raw material elements in size collectively corresponds to a thickness distribution of the piezoelectric device.

In the aforementioned piezoelectric device, the piezoelectric element may have a plurality of laminated sheet-like raw material elements and a plurality of electrodes spaced apart from each other at a predetermined distance. The present invention makes it possible for an electric field strength applied to the piezoelectric device to maintain constant, thereby resulting in the fact that the polarization state of the piezoelectric device maintains constant as well as the piezoelectric device is kept from being excessively distorted so that the piezoelectric device is not cracked. Furthermore, the piezoelectric device according to the present invention, which has a construction produced through the steps of laminating a plurality of sheet-like raw material elements respectively having thicknesses collectively in accordance with a thickness distribution of the piezoelectric device to produce a piezoelectric element, and imparting pressing forces to the piezoelectric element to have the piezoelectric element molded into a predetermined shape, makes it possible for a manufacturer to produce a piezoelectric device having a predetermined uneven thickness distribution with ease, while eliminating the need of carrying out any technically-difficult minute machining processing such as for example a grinding processing. Furthermore, a plurality of piezoelectric devices equal in shape to one another can be constantly produced with high precision because of the fact that the shape of the die is simply transferred to them. The present invention makes it possible for a manufacturer to produce a piezoelectric device having a desired thickness distribution with increased flexibility by adaptively laminating a plurality of sheet-like raw material elements respectively having thicknesses collectively in accordance with the desired thickness.

In accordance with the present invention, there is provided an ultrasonic probe comprising a piezoelectric device having a construction produced through the steps of: (c) producing a first piezoelectric body having a non-plane first surface and a plane second surface opposite to the first surface, and a second piezoelectric body having a plane first surface and a plane second surface opposite to the first surface, the second piezoelectric body having electrodes respectively on the first and second surfaces; and
(d) fixedly connecting the first piezoelectric body to the second piezoelectric body with the second surface of the first piezoelectric body held in contact with the first surface of the second piezoelectric body. The present invention makes it possible for a manufacturer to produce a piezoelectric device having a predetermined uneven thickness distribution with ease, while eliminating the need of carrying out any technically-difficult minute machining processing such as for example a grinding processing, thereby resulting in the fact the piezoelectric device is kept from being excessively distorted so that the piezoelectric device is not cracked. In addition, the present invention makes it possible for a manufacturer to constantly produce a plurality of piezoelectric devices equal in shape to one another with high precision because of the fact that the shape of the die is simply transferred to them, thereby resulting in the fact the piezoelectric device thus produced can reliably operate without being influenced by differences among piezoelectric devices. The piezoelectric device having electrodes spaced apart from each other at a constant distance although the piezoelectric device has an uneven thickness distribution can maintain its polarization state constant, thereby ensuring that ultrasonic waves are transmitted and received with high reliability.

In accordance with the present invention, there is provided an ultrasonic diagnostic apparatus equipped with an ultrasonic probe comprising a piezoelectric device having a construction produced through the steps of: (c) producing a first piezoelectric body having a non-plane first surface and a plane second surface opposite to the first surface, and a second piezoelectric body having a plane first surface and a plane second surface opposite to the first surface, the second piezoelectric body having electrodes respectively on the first and second surfaces; and (d) fixedly connecting the first piezoelectric body to the second piezoelectric body with the second surface of the first piezoelectric body held in contact with the first surface of the second piezoelectric body. The ultrasonic probe thus constructed has an advantage of stably operating without being influenced by differences among piezoelectric devices. The ultrasonic diagnostic apparatus thus constructed can carry out an ultrasound diagnosis with high reliability, taking the advantage of the ultrasonic probe.

In accordance with the present invention, there is provided a nondestructive testing apparatus equipped with an ultrasonic probe comprising a piezoelectric device having a construction produced through the steps of: (c) producing a first piezoelectric body having a non-plane first surface and a plane second surface opposite to the first surface, and a second piezoelectric body having a plane first surface and a plane second surface opposite to the first surface, the second piezoelectric body having electrodes respectively on the first and second surfaces; and (d) fixedly connecting the first piezoelectric body to the second piezoelectric body with the second surface of the first piezoelectric body held in contact with the first surface of the second piezoelectric body. The ultrasonic probe thus constructed has an advantage of stably operating without being influenced by differences among piezoelectric devices. The nondestructive testing apparatus thus constructed can carry out a nondestructive test with high reliability, taking the advantage of the ultrasonic probe.

### BRIEF DESCRIPTION OF THE DRAWINGS

The features and advantages of a method of producing a piezoelectric device, a piezoelectric device, an ultrasonic probe, an ultrasonic diagnostic apparatus, and a nondestructive testing device according to the present invention will be more clearly understood from the following detailed description when considered in connection with the accompanying drawings.

FIG. 1 is a diagram explaining a first preferred embodiment of a method of producing a piezoelectric device according to the present invention.

FIG. 2 is a diagram explaining another pressing process (using front, back, right, and left die walls) forming part of the first embodiment of the method according to the present invention.

FIG. 3 is a diagram explaining a second preferred embodiment of a method of producing a piezoelectric device according to the present invention.

FIG. 4 is a diagram explaining another laminating process (laminating a plurality of sheet-like raw material elements equal in shape to one another) forming part of the second embodiment of the method according to the present invention.

FIG. 5 is a diagram explaining a third preferred embodiment of a method of producing a piezoelectric device according to the present invention.

FIG. 6 is a diagram showing a piezoelectric device to which another embodiment of a method of producing a piezoelectric device (an edge cutting process is excluded) is applicable.

FIG. 7 is a diagram showing a piezoelectric device to which another embodiment of a method of producing a piezoelectric device (an edge cutting process is excluded) is applicable.

FIG. 8 is a diagram explaining another laminating process (laminating a plurality of raw material elements respectively formed with through bores equal in shape to one another) forming part of the third embodiment of the method according to the present invention.

FIG. 9 is a diagram explaining a fourth preferred embodiment of a method of producing a piezoelectric device according to the present invention.

FIG. 10 is a diagram explaining another pressing process (pressing forces are imparted in vertical, lateral, and longitudinal pressing directions) forming part of the fourth embodiment of the method according to the present invention.

FIG. 11 is a diagram explaining another laminating process (laminating a plurality of sheet-like raw material elements different in width from one another along a width direction) forming part of the fourth embodiment of the method according to the present invention.

FIG. 12 is a schematic block diagram showing a fifth preferred embodiment of a piezoelectric device according to the present invention.

FIG. 13 is a diagram explaining a fifth preferred embodiment of a method of producing a piezoelectric device according to the present invention.

FIG. 14 is a diagram explaining a sixth preferred embodiment of a method of producing a piezoelectric device according to the present invention.

FIG. 15 is a diagram explaining a seventh preferred embodiment of a method of producing a piezoelectric device according to the present invention.

FIG. 16 is a diagram explaining another laminating process (laminating a plurality of raw material elements equal in shape to one another for a thick portion) forming part of the seventh embodiment of the method according to the present invention.

FIG. 17 is a diagram explaining an eighth preferred embodiment of a method of producing a piezoelectric device according to the present invention.

FIG. 18 is a diagram explaining another laminating process (laminating a plurality of raw material elements respectively formed with through bores equal in shape to one another) forming part of the eighth embodiment of the method according to the present invention.

FIG. 19 is a schematic diagram showing another eighth embodiment of the piezoelectric device (having a plurality of internal electrodes constituted by two layers) according to the present invention.

FIG. 20 is a schematic block diagram showing a ninth preferred embodiment of an ultrasonic probe according to the present invention.

FIG. 21 is a schematic block diagram showing a tenth preferred embodiment of an ultrasonic probe according to the present invention.

FIG. 22 is a schematic block diagram showing an eleventh preferred embodiment of an ultrasonic diagnostic apparatus according to the present invention.

FIG. 23 is a schematic block diagram showing a twelfth preferred embodiment of a nondestructive testing apparatus according to the present invention.

FIG. 24 is a schematic block diagram showing a conventional ultrasonic probe.

FIG. 25 is a diagram showing a method of producing a conventional piezoelectric device available for a conventional ultrasonic probe.

FIG. 26 is a diagram showing another method of producing a conventional piezoelectric device available for a conventional ultrasonic probe.

### BEST MODE FOR CARRYING OUT THE INVENTION

Preferred embodiments of the present invention will now be described in detail in accordance with the accompanying drawings.

[First Embodiment]

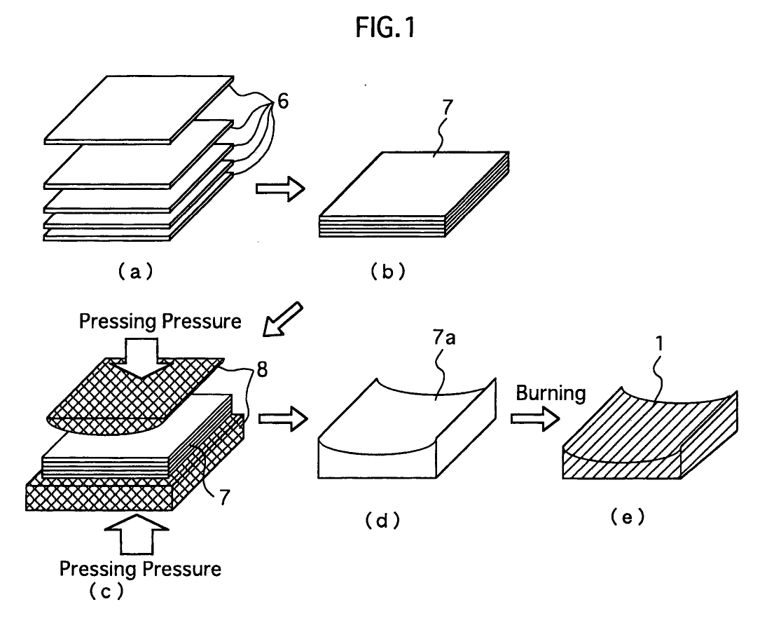

Referring now to FIG. 1 of the drawings, there is shown a first preferred embodiment of a method of producing a piezoelectric device 1, comprising: molding and laminating processes (first step (a)) of molding one or more raw material elements 6 including at least one piezoelectric material to form a predetermined piezoelectric element 7 (raw piezoelectric element); and a pressing process (second step (b)) imparting pressing forces to the piezoelectric element 7 to have the piezoelectric element 7 molded into a predetermined shape.

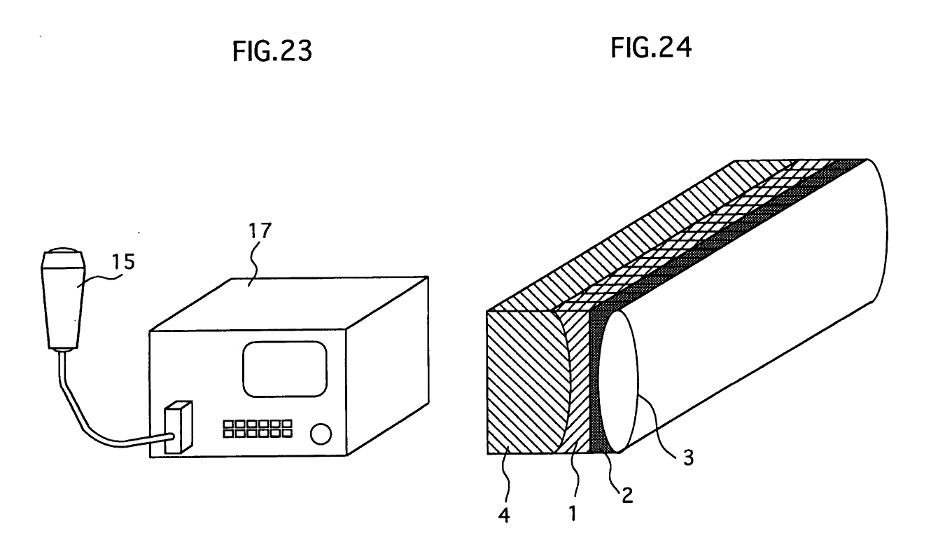

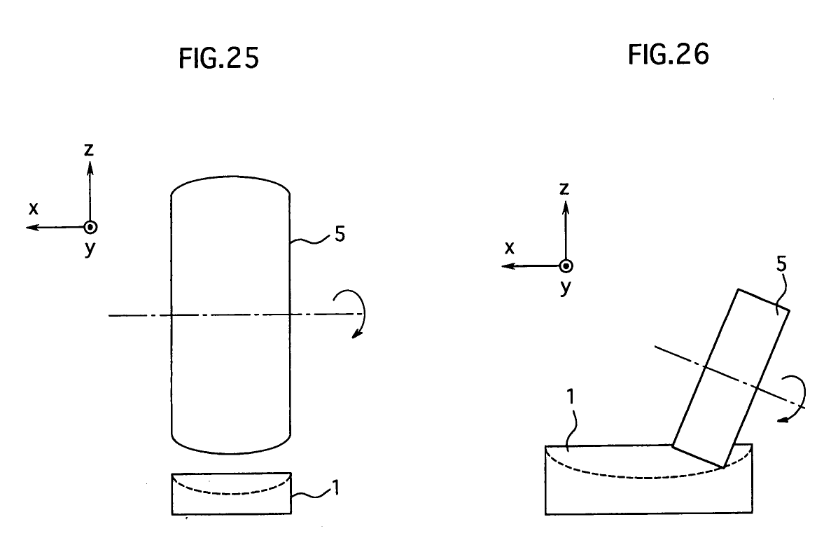

The present embodiment of the piezoelectric device 1 has a plane first surface and a concave second surface opposite to the first surface. The second surface has a thickness concavely curved in a manner that the thickness of the second surface gradually increases from a center portion toward end portions. The piezoelectric device 1 in part constitutes an ultrasonic probe (shown FIG. 20) to be used for an ultrasonic diagnostic apparatus (shown in FIG. 22) or a nondestructive testing device (shown in FIG. 23).

A process of producing a piezoelectric device 1 comprises: a molding process of molding raw materials such as for example piezoelectric ceramic powders to form a plurality of sheet-like raw material elements 6 (not shown in FIG. 1), a laminating process of laminating a plurality of sheet-like raw material elements 6 to form a piezoelectric element 7 (shown in FIGS. 1(a) and 1(b)), a pressing process of imparting pressing forces using a die 8 to the piezoelectric element 7 to have the piezoelectric element 7 molded into a predetermined shape to obtain a piezoelectric element 7a (shown in FIGS. 1(c) and 1(d)), and a burning process of burning the piezoelectric element 7a (shown in FIG. 1(e)).

As shown in FIG. 1, the raw material elements 6 are flexible and capable of being deformed when a pressing force is imparted to the raw material elements 6. The die 8 is made of a metal material such as for example iron and/or the like, and has a predetermined shape so that the shape of the die 8 is transferred to the piezoelectric element 7. In the pressing process, the die 8 is used to impart pressing forces to the piezoelectric element 7 constituted by a plurality of laminated sheet-like raw material elements 6 to have the piezoelectric element 7 molded into a piezoelectric element 7a having a predetermined uneven thickness distribution. The piezoelectric element 7a is shrunken after the burning process. This means that the shape of the die 8 is designed so that the piezoelectric element 7 is molded to form a piezoelectric device 1 having a predetermined uneven thickness distribution in view of a shrinkage caused by the burning process.

In the molding process, raw materials including piezoelectric ceramic powders such as for example PZT powders are mixed with a binding agent (including a plasticizer, if required) and immersed in a solvent. A plurality of raw material elements are then extracted from the solvent by way of, for example, a Doctor Blade technique to form a plurality of sheet-like raw material elements 6 each having a thickness in a range of a few ten microns to a few hundred microns.

In the laminating process, one or more sheet-like raw material elements 6 as shown in FIG. 1(a) are laminated to form a piezoelectric element 7 as shown in FIG. 1(b). Here, the number and the thickness of sheet-like raw material elements 6 to be laminated are calculated in accordance with the thickness distribution of the piezoelectric device 1 in view of a shrinkage caused by the burning process so as to obtain a piezoelectric device 1 having a predetermined thickness distribution after the burning process. While being laminated, the sheet-like raw material elements 6 may be pressed and heated if required.

In the pressing process, the shape and the thickness distribution of the die 8 can be transferred to the piezoelectric element 7. In the present invention, the die 8 made of a metal material such as for example iron and/or the like is used to impart pressing forces to the piezoelectric element 7 in thickness directions as shown in FIG. 1(c) to have the piezoelectric element 7 molded into a piezoelectric element 7a having a predetermined uneven thickness distribution as shown in FIG. 1(d).

In the burning process, the piezoelectric element 7a is not processed by any machining means such as for example grinding means, but burned to produce a piezoelectric device 1 having a predetermined uneven thickness distribution. In this manner, a plurality of piezoelectric devices can be constantly produced with high precision because of the fact that the shape of the die 8 is simply transferred to them.

As will be seen from the foregoing description, it is to be understood that the present embodiment of the method of producing a piezoelectric device according to the present invention, comprising molding and laminating processes of molding one or more raw material elements 6 including at least one piezoelectric material to form a predetermined piezoelectric element 7; and a pressing process of imparting pressing forces to the piezoelectric element 7 to have the piezoelectric element 7 molded into a predetermined shape can produce a piezoelectric device having a predetermined thickness distribution without carrying out any technically-difficult machining processing such as for example a grinding processing. This means that the present embodiment of the method of producing a piezoelectric device, comprising a process of laminating a plurality of sheet-like raw material elements 6 each having an extremely thin thickness to form a piezoelectric element 7 can adaptively produce a piezoelectric device 1 having any thickness by calculating the number of sheet-like raw material elements 6 to be laminated in accordance with the thickness of the piezoelectric device 1 in advance. Furthermore, a plurality of piezoelectric devices equal in shape to one another can be constantly produced with high precision by the reason that the shape of the die 8 is transferred to them.

The first embodiment of the piezoelectric device 1 thus produced comprises a piezoelectric element 7 having one or more raw material elements 6 including a piezoelectric material, in which pressing forces have been imparted to the piezoelectric element 7 to have the piezoelectric element 7 molded. The present embodiment makes it possible for a manufacturer to produce a piezoelectric device having a thickness distribution with ease and high precision.

Though it has been described in the present embodiment that the producing method comprises a laminating process of laminating a plurality of sheet-like raw material elements 6 to produce a piezoelectric element 7, the same effect can still be obtained even when only one raw material element 6 is used as long as the raw material element 6 has a thickness approximately corresponding to the thickness of the piezoelectric device 1. In such a case, a laborious work of laminating a plurality of raw material elements 6 to produce a piezoelectric element 7 can be eliminated.

Though it has been described in the present embodiment that the piezoelectric device 1 thus produced has a concave surface having a thickness concavely curved in a manner that the thickness of the surface gradually increases from a center portion toward end portions, the same effect can still be obtained even when the surface of the piezoelectric device has an arbitrary shape such as for example a convex surface, convexo-concave surface, or the like, by adaptively modifying the shape of the die 8 in accordance with the desired shape of the surface of the piezoelectric device.

Furthermore, though it has been described in the present embodiment that the piezoelectric device 1 thus produced is in the form of a quadrilateral sheet shape, the same effect can still be obtained even when the piezoelectric device is in the form of an arbitrary shape such as, for example, a disc sheet shape, by adaptively modifying the shapes of the raw material elements 6 and the die 8 in accordance with the desired shape of the piezoelectric device.

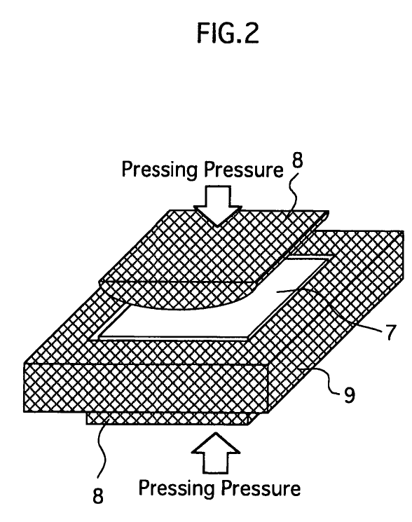

Furthermore, while it has been described in the present embodiment that pressing forces are imparted to the piezoelectric element 7 in pressing directions without holding the piezoelectric element 7 with respect to directions perpendicular to the pressing directions as shown in FIG. 1(c), the same effect can still be obtained even when pressing forces are imparted to the piezoelectric element 7 in pressing directions while holding the piezoelectric element 7 with a die wall 9 made of a metal material such as for example iron and/or the like, and extending in front, back, right, and left directions perpendicular relationship to the pressing directions as shown in FIG. 2. In such a case, the piezoelectric element 7 is prevented from being excessively spread in the front, back, right, and left directions perpendicular to the pressing directions during the pressing process.

[Second Embodiment]

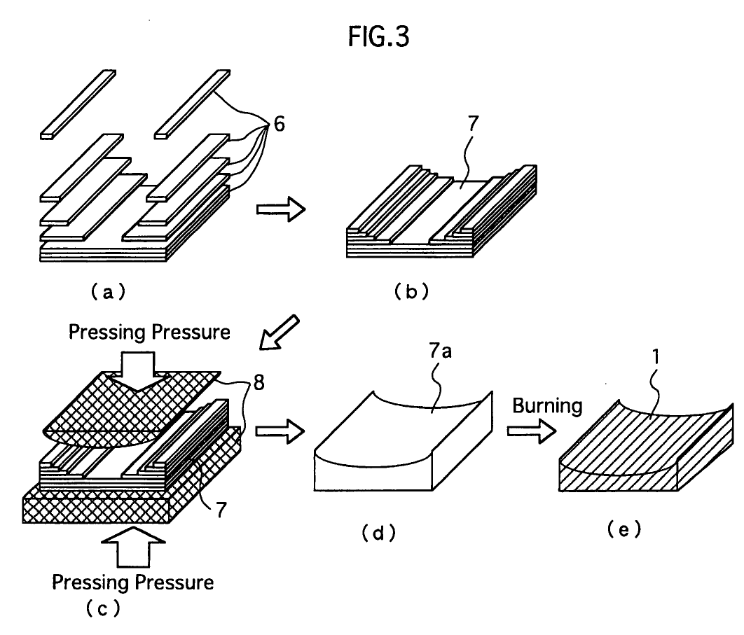

Referring then to FIG. 3 of the drawings, there is shown a second preferred embodiment of a method of producing a piezoelectric device 1. The present embodiment of the producing method is different from the first embodiment of the producing method in the fact that the molding and laminating process (first step (a)) further has a process of laminating a plurality of raw material elements 6 (sheet-like raw material elements) respectively having thicknesses collectively in accordance with a thickness distribution of the piezoelectric device. Preferably, the shape and the number of sheet-like raw material elements 6 to be laminated should be calculated in accordance with the thickness distribution of the piezoelectric device 1. The present embodiment of the producing method has an additional effect of being capable of producing a piezoelectric device 1 having a predetermined thickness distribution with increased flexibility by adaptively laminating a plurality of raw material elements 6 respectively having thicknesses collectively in accordance with the thickness distribution of the piezoelectric device.

The present embodiment of the piezoelectric device 1 has a plane first surface and a concave second surface opposite to the first surface. The second surface has a thickness concavely curved in a manner that the thickness of the second surface gradually increases from a center portion toward end portions. The piezoelectric device 1 in part constitutes an ultrasonic probe (shown FIG. 20) to be used for an ultrasonic diagnostic apparatus (shown in FIG. 22) or a nondestructive testing device (shown in FIG. 23).

Similar to the first embodiment of the producing process, in the present embodiment, a process of producing a piezoelectric device 1 comprises: a molding process of molding raw materials such as for example piezoelectric ceramic powders to form a plurality of sheet-like raw material elements 6 (not shown in FIG. 3), a laminating process of laminating a plurality of sheet-like raw material elements 6 to form a piezoelectric element 7 (shown in FIGS. 3(a) and 3(b)), a pressing process of imparting pressing forces using a die 8 to the piezoelectric element 7 to have the piezoelectric element 7 molded into a predetermined shape (shown in FIGS. 3(c) and 3(d)), and a burning process of burning the piezoelectric element 7a (shown in FIG. 3(e)).

As shown in FIG. 3, the raw material elements 6, made of a piezoelectric material, a binding agent, and the like, are flexible and capable of being deformed when pressing forces are imparted to the raw material elements 6, as described hereinearlier. The die 8 is made of a metal material such as for example iron and/or the like, and has a predetermined shape so that the shape of the die 8 is transferred to the piezoelectric element 7. In the pressing process, the die 8 is used to impart pressing forces to the piezoelectric element 7 to have the piezoelectric element 7 molded into a piezoelectric element 7a having a predetermined uneven thickness distribution. The shape of the die 8 is designed so that the piezoelectric element 7 is molded to form a piezoelectric device 1 having a predetermined uneven thickness distribution in view of a shrinkage caused by the burning process.

In the molding process, raw materials including piezoelectric ceramic powders such as for example PZT powders are mixed with a binding agent (including a plasticizer, if required) and immersed in a solvent. A plurality of raw material elements are then extracted from the solvent by way of, for example, a Doctor Blade technique to form a plurality of sheet-like raw material elements 6 each having a thickness in a range of a few ten microns to a few hundred microns, and a unique width, if required.

In the laminating process, one or more sheet-like raw material elements 6 as shown in FIG. 3(a) are laminated to form a piezoelectric element 7 as shown in FIG. 3(b). Here, the number and the thicknesses of sheet-like raw material elements 6 to be laminated are calculated in accordance with the thickness distribution of the piezoelectric device 1 in view of a shrinkage caused by the burning process so as to obtain a piezoelectric device 1 having a predetermined thickness distribution after the burning process. Furthermore, one or more sheet-like raw material elements 6 respectively having shapes collectively corresponding to the thickness distribution of the piezoelectric device are laminated. For example, one or more sheet-like raw material elements 6 respectively having widths collectively corresponding to the thickness distribution of the piezoelectric device may be laminated. Alternatively, the number of sheet-like raw material elements 6 may be laminated in accordance with the thickness distribution of the piezoelectric device. In the present embodiment, in order to produce a piezoelectric device 1 having a thickness concavely curved in a manner that the thickness of the piezoelectric device gradually increases from a center portion toward end portions, a plurality of sheet-like raw material elements 6 are laminated in a manner that the widths of the sheet-like raw material elements 6 decreases from a low layer toward a top layer on the both end portions. Similar to the first embodiment of the producing process, while being laminated, the sheet-like raw material elements 6 may be pressed and heated if required.

In the pressing process, similar to the first embodiment of the producing process, a die 8 made of a metal material such as for example iron and/or the like is used to impart pressing forces to the piezoelectric element 7 in thickness directions as shown in FIG. 3(c) to have the piezoelectric element 7 molded into a piezoelectric element 7a having a predetermined uneven thickness distribution as shown in FIG. 3(d). The present embodiment of the producing method can restrict the pressing forces imparted by the die 8 to the piezoelectric element 7 to a certain degree, prevent the piezoelectric element 7 from being unnecessarily and abnormally deformed, and reduce a residual stress remaining in the piezoelectric element 7a by the reason that the piezoelectric element 7 laminated in the previous laminating process has a shape approximately similar to the thickness distribution of the piezoelectric device 1 as shown in FIG. 3(b). Furthermore, the present embodiment of the producing method can advantageously produce a piezoelectric device whose thickness distribution is so large (the difference between its thin portion and thick portion is extremely large) that the thickness distribution cannot be formed by simply deforming the piezoelectric element 7.

In the burning process, similar to the first embodiment of the producing process, the piezoelectric element 7a is not processed by any machining means such as for example grinding means, but burned to produce a piezoelectric device 1 having a predetermined uneven thickness distribution. In this manner, a plurality of piezoelectric devices can be constantly produced with high precision because of the fact that the shape of the die 8 is simply transferred to them. The same effect can still be obtained even when only one raw material element 6 is used. In such a case, a laborious work of laminating a plurality of raw material elements 6 to produce a piezoelectric element 7 can be eliminated.

As will be seen from the foregoing description, it is to be understood that the present embodiment of the piezoelectric device 1 according to the present invention, comprising a piezoelectric element 7a (raw piezoelectric element) including one or more raw material elements 6 (sheet-like raw material elements) respectively having shapes laminated in accordance with a thickness distribution of the piezoelectric device, for example, widths collectively corresponding to the thickness distribution of the piezoelectric device to form a piezoelectric element 7a can produce a piezoelectric device having a desired thickness distribution with high precision. This means that the present embodiment of the producing method comprising a process of laminating a plurality of sheet-like raw material elements 6 each having an extremely thin thickness to form a piezoelectric element 7 can adaptively produce a piezoelectric device 1 having any thickness distribution by calculating the number of sheet-like raw material elements 6 to be laminated in accordance with the thickness distribution of the piezoelectric device 1 in advance.

Though it has been described in the present embodiment that the piezoelectric device 1 thus produced has a concave surface having a thickness concavely curved in a manner that the thickness of the surface gradually increases from a center portion toward end portions, the same effect can still be obtained even when the surface of the piezoelectric device has an arbitrary shape such as for example a convex surface, convexo-concave surface, or the like, by selectively increasing the number of the raw material elements 6 to be laminated for a thick portion without restricting the shape of the piezoelectric device 1.

Furthermore, though it has been described in the present embodiment that the piezoelectric device 1 thus produced is in the form of a quadrilateral sheet shape, the same effect can still be obtained even when the piezoelectric device is in the form of an arbitrary shape such as, for example, a disc sheet shape, by adaptively modifying the shapes of the raw material elements 6 and the die 8 in accordance with the desired shape of the piezoelectric device.

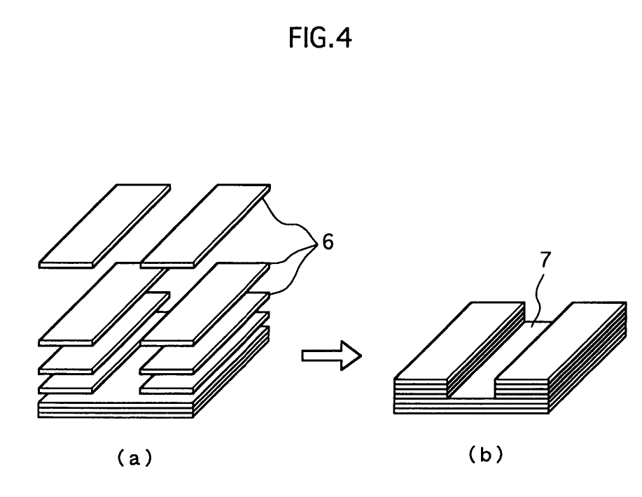

Furthermore, while it has been described in the present embodiment that a plurality of raw material elements 6 are laminated to produce a piezoelectric device 1 in a manner that the widths of the raw material elements 6 decreases from a low layer toward a top layer on the both end portions, the same effect can still be obtained even when a plurality of raw material elements 6 equal in width or shape to one another are laminated on the both ends to produce a piezoelectric element 7 as shown in FIG. 4. In such a case, a laborious work of carefully laminating the raw material elements 6 in accordance with their widths is eliminated, and the shapes of the raw material elements 6 to be laminated are not restricted by the reason that the number of the raw material elements 6 to be laminated can be selectively increased for a thick portion.

[Third Embodiment]

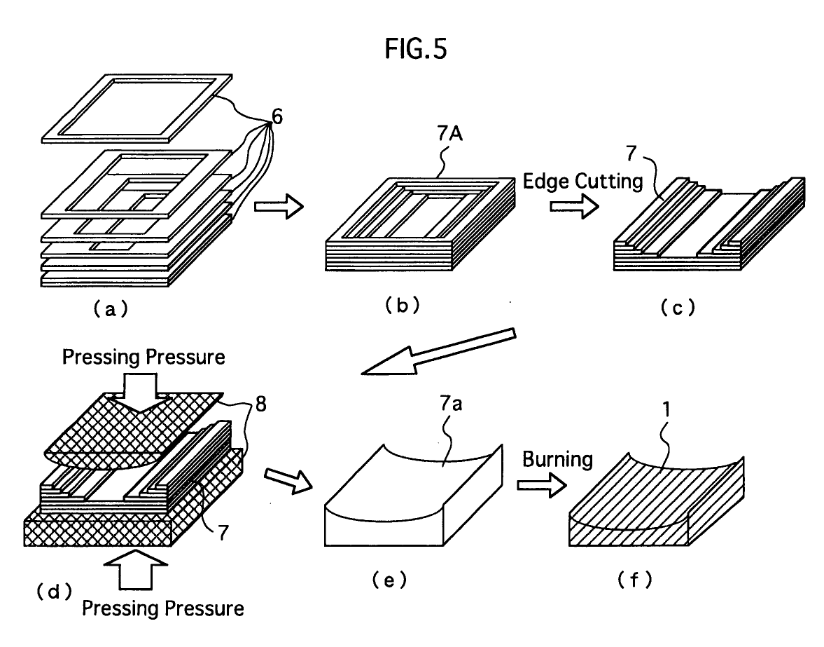

Referring then to FIG. 5 of the drawings, there is shown a third preferred embodiment of a method of producing a piezoelectric device 1. The present embodiment of the producing method is different from the first embodiment of the producing method in the fact that the molding and laminating process (first step (a)) further has a process of laminating one or more raw material elements respectively formed with through bores in accordance with a thickness distribution of the piezoelectric device 1. The present embodiment of the producing method has an additional effect of being capable of producing a piezoelectric device 1 having a predetermined shape and thickness distribution with increased flexibility.

The present embodiment of the piezoelectric device 1 has a plane first surface and a concave second surface opposite to the first surface. The second surface has a thickness concavely curved in a manner that the thickness of the second surface gradually increases from a center portion toward end portions. The piezoelectric device 1 in part constitutes an ultrasonic probe (shown FIG. 20) to be used for an ultrasonic diagnostic apparatus (shown in FIG. 22) or a nondestructive testing device (shown in FIG. 23).

Similar to the first embodiment of the producing process, in the present embodiment, a process of producing a piezoelectric device 1 comprises: a molding process of molding raw materials such as for example piezoelectric ceramic powders to form a plurality of sheet-like raw material elements (not shown in FIG. 5), a die-cutting process of die-cutting the sheet-like raw material elements, as many as required, to obtain a plurality of window frame-like raw material elements 6 respectively formed with through bores in the form of rectangular window shapes (not shown in FIG. 5), a laminating process of laminating a plurality of window frame-like raw material elements 6 and a plurality of sheet-like raw material elements 6 to form a piezoelectric element 7A (shown in FIGS. 5(a) and 5(b)), an edge cutting process of cutting off the front end rear edges of the piezoelectric element 7A (shown in FIG. 5(c)) to obtain a piezoelectric element 7, a pressing process of imparting pressing forces using a die 8 to the piezoelectric element 7 to have the piezoelectric element 7 molded into a predetermined shape to obtain a piezoelectric element 7a (shown in FIGS. 5(d) and 5(e)), and a burning process of burning the piezoelectric element 7a (shown in FIG. 5(f)).

As shown in FIG. 5, the raw material elements 6, made of a piezoelectric material, a binding agent, and the like, are flexible and capable of being deformed when pressing forces are imparted to the raw material elements 6, as described hereinearlier. The die 8 is made of a metal material such as for example iron and/or the like, and has a predetermined shape so that the shape of the die 8 is transferred to the piezoelectric element 7. In the pressing process, the die 8 is used to impart pressing forces to the piezoelectric element 7 to have the piezoelectric element 7 molded into a piezoelectric element 7a having a predetermined uneven thickness distribution. The shape of the die 8 is designed so that the piezoelectric element 7 is molded to form a piezoelectric device 1 having a predetermined uneven thickness distribution in view of a shrinkage caused by the burning process.

In the molding process, raw materials including piezoelectric ceramic powders such as for example PZT powders are mixed with a binding agent (including a plasticizer, if required) and immersed in a solvent. A plurality of raw material elements are then extracted from the solvent by way of, for example, a Doctor Blade technique to form a plurality of sheet-like raw material elements each having a thickness in a range of a few ten microns to a few hundred microns.

In the die-cutting process, the sheet-like raw material elements, as many as required, are die-cut to obtain a plurality of window frame-like raw material elements 6 respectively formed with through bores different in shape and size.

In the laminating process, one or more sheet-like raw material elements 6 including window frame-like raw material elements 6 as shown in FIG. 5(a) are laminated to form a piezoelectric element 7A as shown in FIG. 5(b). Here, the number and the thicknesses of sheet-like raw material elements 6 to be laminated are calculated in accordance with the thickness distribution of the piezoelectric device 1 in view of a shrinkage caused by the burning process so as to obtain a piezoelectric device 1 having a predetermined thickness distribution after the burning process. In the present embodiment, the piezoelectric device 1 to be produced has a thickness concavely curved in a manner that the thickness of the piezoelectric device 1 gradually increases from a center portion toward end portions along the minor axis. In accordance with the thickness distribution of the piezoelectric device 1 to be produced, one or more sheet-like raw material elements 6 respectively formed with through-bores are laminated. Preferably, the through bores of the one or more sheet-like raw material elements 6 to be laminated should be in size collectively in accordance with the thickness distribution of the piezoelectric device 1. More specifically, a plurality of window frame-like raw material elements 6 are laminated in a manner that the widths of the window frame-like raw material elements 6 gradually decreases, i.e., the size of each of the through bores of the window frame-like raw material elements 6 gradually increases from a low layer toward a top layer on the both end portions as shown in FIG. 5(b). Similar to the first embodiment of the producing process, while being laminated, the sheet-like raw material elements 6 may be pressed and heated if required.

Each of the raw material elements 6 has an outer edge. Preferably, the raw material elements 6 may be made in a manner that the outer edges of the raw material elements 6 are equal in shape (size) to one another and the window frame-like raw material elements 6 have through bores accurately die-cut with respect to their outer edges so that the raw material elements 6 can be easily laminated without displacements simply after positioning the raw material elements 6 with respect to their respective outer edges. Alternatively, each of the raw material elements 6 may have at least one perpendicular edge in a manner that the raw material elements 6 have through bores accurately die-cut with respect to their perpendicular edges so that the raw material elements 6 can be easily laminated without displacements simply after positioning the perpendicular edges of the raw material elements 6 although the raw material elements 6 are not equal in shape to one another. Furthermore, the raw material elements 6 may be made in a manner that the through bores of the raw material elements 6 in size collectively correspond to the thickness distribution of the piezoelectric device 1 along a width direction (in the present embodiment, the raw material elements 6 are laminated in a manner that the size of each of the through bores of the raw material elements 6 gradually increases along the width direction from the lower layer to the top layer) so as to form the piezoelectric element 7A having a thickness concavely curved in a manner that the thickness of the piezoelectric element 7A gradually increases from a center portion toward end portions along the minor axis.

In the edge cutting process, unwanted parts of the piezoelectric element 7A collectively constituted by the raw material elements 6 are cut off. The unwanted parts of the piezoelectric element 7A may not be cut off but used as reinforcing parts in the case that the piezoelectric element 7A has such an extremely thin portion that the piezoelectric element 7A as a whole would be abnormally curved and fail to lose its shape when the unwanted parts of the piezoelectric element 7A are cut off. In this case, the unwanted parts of the piezoelectric element 7A may be cut off after the pressing process or the burning process.

In the pressing process, similar to the first embodiment of the producing process, a die 8 made of a metal material such as for example iron and/or the like is used to impart pressing forces to the piezoelectric element 7 in thickness directions as shown in FIG. 5(d) to have the piezoelectric element 7 molded into a piezoelectric element 7a having a predetermined uneven thickness distribution as shown in FIG. 5(e). In the present embodiment of the producing method, the pressing forces imparted by the die 8 to the piezoelectric element 7 is restricted to a certain degree, the piezoelectric element 7 is prevented from being unnecessarily and abnormally deformed, and a residual stress remaining in the piezoelectric element 7a is reduced by the reason that the piezoelectric element 7 laminated in the previous laminating process has a shape approximately similar to the thickness distribution of the piezoelectric device 1 as shown in FIG. 5(c). Furthermore, the present embodiment of the producing method can advantageously produce a piezoelectric device whose thickness distribution is so large (the difference between its thin portion and thick portion is extremely large) that the thickness distribution cannot be formed by simply deforming the piezoelectric element 7.

In the burning process, similar to the first embodiment of the producing process, the piezoelectric element 7a is not processed by any machining means such as for example grinding means, but burned to produce a piezoelectric device 1 having a predetermined uneven thickness distribution. In this manner, a plurality of piezoelectric devices can be constantly produced with high precision because of the fact that the shape of the die 8 is simply transferred to them.

As will be seen from the foregoing description, it is to be understood that the present embodiment of the piezoelectric device 1 according to the present invention, comprising a piezoelectric element 7a (raw piezoelectric element) including one or more raw material elements 6 (sheet-like raw material element) respectively formed with through bores in accordance with a thickness distribution of the piezoelectric device can produce a piezoelectric device having a desired thickness distribution with high precision.

Furthermore, the present embodiment of the producing method comprising a process of laminating a plurality of raw material elements 6 respectively formed with through bores in accordance with a thickness distribution of the piezoelectric device can adaptively produce a piezoelectric device 1 having any shape and thickness distribution.

Though it has been described in the present embodiment that the piezoelectric device 1 thus produced has a concave surface having a thickness concavely curved in a manner that the thickness of the surface gradually increases from a center portion toward end portions, the same effect can still be obtained even when the surface of the piezoelectric device has an arbitrary shape such as for example a convex surface, convexo-concave surface, or the like, by selectively increasing the number of the raw material elements 6 to be laminated for a thick portion 1 in view of the positions, the sizes, and the number of their through bores without restricting the shape of the piezoelectric device.

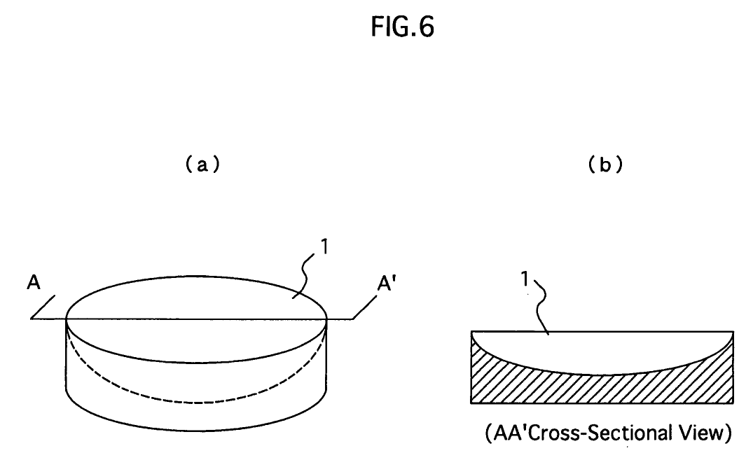

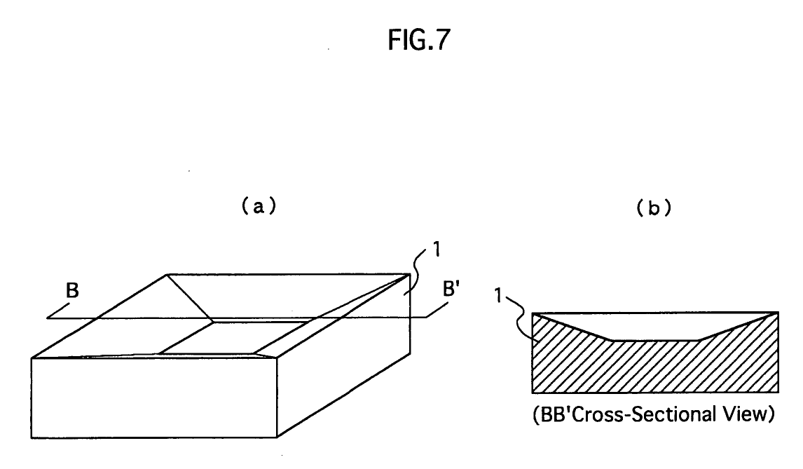

Furthermore, though it has been described in the present embodiment that the unwanted parts of the piezoelectric element 7A are cut off by the reason that the piezoelectric device 1 thus produced should have a concave surface having a thickness concavely curved in a manner that the thickness of the surface gradually increases from a center portion toward end portions (two directions), the same effect can still be obtained even when the piezoelectric device 1 thus produced has a concave surface having a thickness concavely curved in a manner that the thickness of the surface gradually increases from a center portion toward end portions as shown in FIGS. 6(a) and 6(b) or FIGS. 7(a) and 7(b). In such a case, the piezoelectric element 7A has no unwanted parts to be cut off, and the edge cutting process is accordingly eliminated.

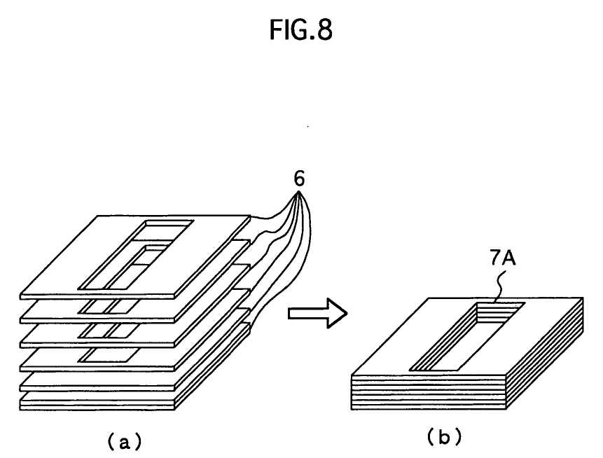

Furthermore, while it has been described in the present embodiment that a plurality of raw material elements 6 are laminated to obtain a piezoelectric element 7A similar in shape to the piezoelectric device 1 to be produced in a manner that the widths of through bores of the raw material elements 6 increases from a low layer toward a top layer, the same effect can still be obtained even when a plurality of raw material elements 6 respectively having through bores equal in width or shape to one another as shown in FIG. 8(a) are laminated to produce a piezoelectric element 7A as shown in FIG. 8(b) as long as the piezoelectric element 7A is similar in shape to the piezoelectric device 1 to be produced, and the number of the raw material elements 6 to be laminated is selectively increased for a thick portion in view of the positions, the sizes, and the number of their through bores. In such a case, a laborious work of selectively laminating the raw material elements 6 in accordance with the widths of their through bores is eliminated without restricting the shape of the piezoelectric device 1.

[Fourth Embodiment]

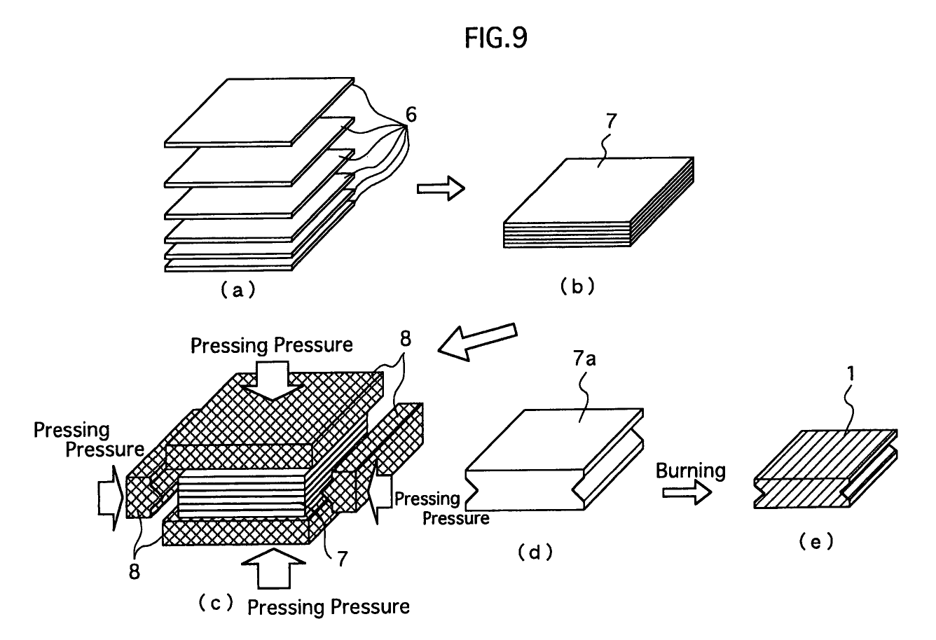

Referring then to FIG. 9 of the drawings, there is shown a fourth preferred embodiment of a method of producing a piezoelectric device 1. The present embodiment of the producing method is different from the first embodiment of the producing method in the fact that pressing forces are imparted to the piezoelectric element 7 in laminating directions, along which the raw material elements 6 are laminated, and directions perpendicular to the laminating directions. The present embodiment of the producing method has an additional effect of being capable of producing a piezoelectric device 1 having a predetermined uneven width distribution without carrying out any technically-difficult minute machining processing.

The present embodiment of the piezoelectric device 1 has a width concavely curved in a manner that the width of the piezoelectric device 1 gradually increases from a middle portion toward upper and lower end portions. The piezoelectric device 1 in part constitutes an ultrasonic probe (shown FIG. 20) to be used for an ultrasonic diagnostic apparatus (shown in FIG. 22) or a nondestructive testing device (shown in FIG. 23).

Similar to the first embodiment of the producing process, in the present embodiment, a process of producing a piezoelectric device 1 comprises: a molding process of molding raw materials such as for example piezoelectric ceramic powders to form a plurality of sheet-like raw material elements 6 (not shown in FIG. 9), a laminating process of laminating a plurality of sheet-like raw material elements 6 to form a piezoelectric element 7 (shown in FIGS. 9(a) and 9(b)), a pressing process of imparting pressing forces using a die 8 in four directions to the piezoelectric element 7 to have the piezoelectric element 7 molded into a predetermined shape (shown in FIG. 9(c)), and a burning process of burning the piezoelectric element 7a (shown in FIGS. 9(d) and 9(e)).

As shown in FIG. 9, the raw material elements 6, made of a piezoelectric material, a binding agent, and the like, are flexible and capable of being deformed when pressing forces are imparted to the raw material elements 6, as described hereinearlier. The die 8 is made of a metal material such as for example iron and/or the like, and has a predetermined shape so that the shape of the die 8 is transferred to the piezoelectric element 7. In the pressing process, the die 8 is used to impart pressing forces to the piezoelectric element 7 to have the piezoelectric element 7 molded into a piezoelectric element 7a having a predetermined uneven thickness distribution. The shape of the die 8 is designed so that the piezoelectric element 7 is molded to form a piezoelectric device 1 having a predetermined uneven thickness distribution in view of a shrinkage caused by the burning process.

In the molding process, raw materials including piezoelectric ceramic powders such as for example PZT powders are mixed with a binding agent (including a plasticizer, if required) and immersed in a solvent. A plurality of raw material elements are then extracted from the solvent by way of, for example, a Doctor Blade technique to form a plurality of sheet-like raw material elements 6 each having a thickness in a range of a few ten microns to a few hundred microns.

In the laminating process, similar to the first embodiment of the producing process, one or more sheet-like raw material elements 6 as shown in FIG. 9(a) are laminated to form a piezoelectric element 7 as shown in FIG. 9(b). Here, the number and the thicknesses of sheet-like raw material elements 6 to be laminated are calculated in accordance with the thickness distribution of the piezoelectric device 1 in view of a shrinkage caused by the burning process so as to obtain a piezoelectric device 1 having a predetermined thickness distribution after the burning process. While being laminated, the sheet-like raw material elements 6 may be pressed and heated if required.

In the pressing process, a die 8 made of a metal material such as for example aluminum, brass, and/or the like, having a solidity required for the pressing process, and capable of being easily worked, is used to impart pressing forces to the piezoelectric element 7 as shown in FIG. 9(c). In the present embodiment, the die 8 has two vertical pressing surfaces opposing to each other and to be held in pressing contact with the piezoelectric element 7 in vertical directions and two convex-shaped lateral pressing surfaces opposing to each other and to be held in pressing contact with the piezoelectric element 7 in lateral directions. Using the die 8, pressing forces are imparted to the piezoelectric element 7 to have the piezoelectric element 7 molded into a piezoelectric element 7a having an uneven width distribution concavely curved in a manner that the width of the piezoelectric element 7a gradually increases from a middle portion toward upper and lower end portions as shown in FIG. 9(d). In the present embodiment, the die 8 is made of a metal material capable of being molded into a desired shape, and the lateral sides of the piezoelectric element 7 constituted by a plurality of thin sheet-like raw material elements 6 are not processed directly by any processing tool. This means that the present embodiment of the producing method can prevent the piezoelectric device 1 from being damaged and constantly produce a plurality of piezoelectric devices with high precision because of the fact that the lateral sides of the piezoelectric element 7 are not processed directly by any processing tool, but held in pressing contact with the lateral pressing surfaces of the die 8 while the pressing forces are imparted, and the shape of the die 8 is simply transferred to them.

In the burning process, the piezoelectric element 7a is not processed by any machining means such as for example grinding means, but burned to produce a piezoelectric device 1 having a predetermined uneven thickness distribution. In this manner, a plurality of piezoelectric devices can be constantly produced with high precision because of the fact that the shape of the die 8 is simply transferred to them as described in the above.

Though it has been described in the present embodiment that the piezoelectric device 1 thus produced has a shape with a width distribution concavely curved in a manner that the width of the piezoelectric device 1 gradually increases from a middle portion toward upper and lower end portions, the same effect can still be obtained even when the piezoelectric device 1 has a shape with any width distribution, by imparting pressing forces to the piezoelectric element 7 in the lateral directions using a die 8 molded into a shape having a width distribution corresponding to that of the piezoelectric device 1.

Furthermore, though it has been described in the present embodiment that the piezoelectric device 1 thus produced has a shape with an uneven width distribution in lateral directions, the same effect can still be obtained even when the piezoelectric device 1 has a shape with any uneven width distribution in longitudinal directions perpendicular to the vertical and lateral directions, or when the piezoelectric device 1 has a shape with any uneven width distribution both in the lateral and the longitudinal directions, by adaptively imparting pressing forces to the piezoelectric element 7 in the lateral directions or both in the lateral and the longitudinal directions using a die 8.

Furthermore, though it has been described in the present embodiment that pressing forces are imparted to the piezoelectric element 7 using a die 8 having plane pressing surfaces in the vertical directions, i.e., thickness directions to produce a piezoelectric device 1 having a plane thickness distribution, the same effect can still be obtained even when the piezoelectric device 1 has a shape having both an uneven width distribution in the lateral direction and an uneven thickness distribution in the vertical directions by selectively adopting a die 8 having a shape in accordance with the shape of the piezoelectric device 1 to be produced.

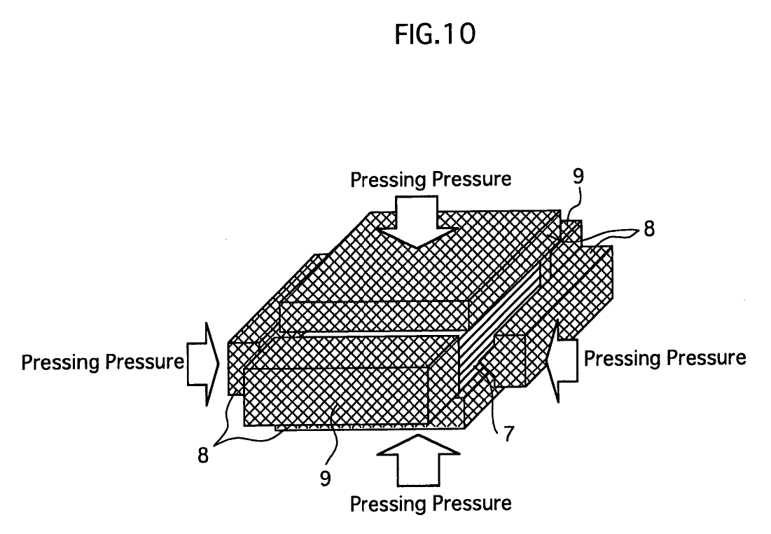

Furthermore, while it has been described in the present embodiment that pressing forces are imparted to the piezoelectric element 7 in the vertical and lateral pressing directions without holding the piezoelectric element 7 with respect to the longitudinal directions, the same effect can still be obtained even when pressing forces are imparted to the piezoelectric element 7 in the vertical and lateral pressing directions while holding the piezoelectric element 7 with a die wall 9 made of a metal material such as for example aluminum, brass, and/or the like, and extending in perpendicular relationship to the vertical and lateral pressing directions as shown in FIG. 10. In such a case, the piezoelectric element 7 is prevented from being excessively spread in the longitudinal directions during the pressing process.

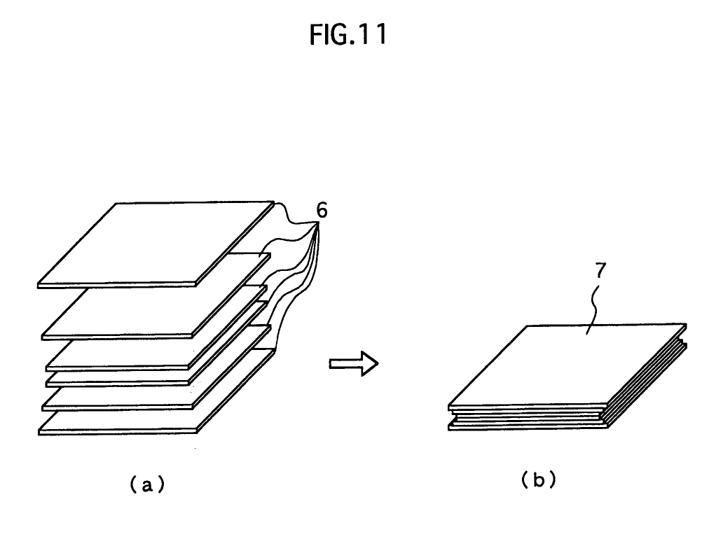

Furthermore, though it has been described in the present embodiment that the producing method comprises a pressing process of imparting pressing forces in lateral directions using a die 8 to the piezoelectric element 7 constituted by a plurality of laminated raw material elements 6 identical in shape to one another, the same effect can still be obtained even when a plurality of raw material elements 6 different in lateral width (length in lateral direction) from one another as shown in FIG. 11(a) are laminated to produce a piezoelectric element 7 approximately similar in shape to the piezoelectric device 1 to be produced as shown in FIG. 11(b) before the pressing process. As will be seen from the foregoing description, it is to be understood that the producing method, which comprises a laminating process of laminating a plurality of raw material elements 6 different in lateral width from one another in a manner that the lateral width of the raw material elements 6 increases from a middle portion toward upper and lower end portions can adaptively produce a piezoelectric device 1 having any uneven width distribution with high precision. Further, the pressing forces imparted by the die 8 to the piezoelectric element 7 are restricted to a certain degree, the piezoelectric element 7 is prevented from being unnecessarily and abnormally deformed, and a residual stress remaining in the piezoelectric element 7a is reduced.

[Fifth Embodiment]

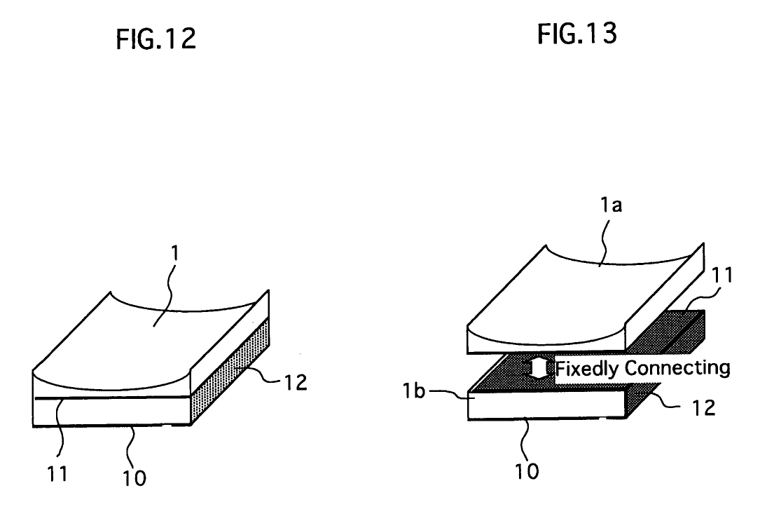

Referring to FIG. 12 of the drawings, there is shown a fifth preferred embodiment of the piezoelectric device 1 comprising a piezoelectric element 7 (raw piezoelectric element) including a plurality of laminated raw material elements 6 (sheet-like raw material elements), an external electrode 10, and an internal electrode 11 (a plurality of electrodes spaced apart from each other at a predetermined distance.

As shown in FIG. 12, the piezoelectric device 1 is made of, for example, piezoelectric ceramics, and has a thickness concavely curved in a manner that the thickness of the piezoelectric device 1 gradually increases from a center portion toward end portions along lateral directions. The external electrode 10 is formed on a plane bottom surface of the piezoelectric device 1, and made of, for example, baking silver, gold sputter-coated material, and/or the like. The internal electrode 11 is formed on an inner surface of piezoelectric device 1, spaced apart from and in parallel relationship to the external electrode 10. The piezoelectric device 1 further comprises an extension electrode 12 beside the internal electrode 11 and extending from the internal surface to the bottom surface through a side surface of the piezoelectric device 1 for ease in electrical connection. The extension electrode 12 and the external electrode 10 are spaced apart from each other at a predetermined distance on the bottom surface and electrically insulated from each other.

In the conventional piezoelectric device, electrodes are in general formed on an upwardly exposed upper surface and a downwardly exposed bottom surface of the piezoelectric device. In the case of the conventional piezoelectric device having such a shape as shown in FIG. 12, the first electrode formed on the upper surface of the piezoelectric device is concavely curved and the second electrode formed on the bottom surface is plane. This means that the distance between the first and second electrodes is not constant but varied in a manner that the distance between the first and second electrodes gradually increases from a center portion toward end portions. This leads to the fact that electric field strength applied to the piezoelectric device and thus polarization state of the piezoelectric device become uneven along a lateral direction as shown in FIG. 12 in the event that the piezoelectric device is used and polarized. Further, the fact that the electric field applied to the thin center portion is greater than the electric field applied to the end portion leads to the fact that the piezoelectric device is caused to be excessively distorted, thereby making it easier for the piezoelectric device to be cracked (microcracked).

On the contrary, in the case of the present embodiment of the piezoelectric device 1 as shown in FIG. 12 comprising an external electrode 10 and an internal electrode 11 spaced apart from each other at a predetermined distance, electric field strength applied to the piezoelectric device and thus polarization state of the piezoelectric device are constant in the event that the piezoelectric device 1 is used and polarized by the reason that the distance between the external electrode and the internal electrode is constant, as well as the piezoelectric device is kept from being excessively distorted so that the piezoelectric device is not cracked (microcracked).

The present embodiment of the method of producing a piezoelectric device 1 will be described hereinlater with reference to FIG. 13. The present embodiment of the piezoelectric device 1 comprises a first piezoelectric body 1a and a second piezoelectric body 1b. The first piezoelectric body 1a has a concave upper surface and a plane lower surface opposite to the upper surface. The second piezoelectric body 1b has a plane upper surface and a plane lower surface opposite to the upper surface, an external electrode 10 formed on the lower surface and an internal electrode 11 formed on the upper surface. The piezoelectric device 1 further comprises an extension electrode 12 extending from the internal surface to the lower surface through a right side surface of the piezoelectric device 1 for ease in an electrical connection. The extension electrode 12 and the external electrode 10 are spaced apart from each other at a predetermined distance on the lower surface and electrically insulated from each other. The first piezoelectric body 1a and the second piezoelectric body 1b are fixedly connected with each other with an adhesive material such as for example an epoxy adhesive material, a silver paste, or the like to produce a piezoelectric device 1.

As will be seen from the foregoing description, it is to be understood that the present embodiment of the piezoelectric device 1 according to the present invention, comprising a piezoelectric element 7 having a plurality of laminated raw material elements 6 and an external electrode 10 and an internal electrode 11 spaced apart from each other at a predetermined distance can keep an electric field strength applied to the piezoelectric device 1 constant and thus realize an even polarization.

Furthermore, the present embodiment of the method of producing a piezoelectric device 1, comprising a process of producing a first piezoelectric body 1a having a non-plane first surface and a plane second surface opposite to the first surface, and a second piezoelectric body 1b having a plane first surface and a plane second surface opposite to the first surface, the second piezoelectric body 1b having an internal electrode 11, an external electrode 10, and an extension electrode 12 on the first and second surfaces; and a process of fixedly connecting the first piezoelectric body 1a to the second piezoelectric body 1b with the second surface of the first piezoelectric body 1a held in contact with the first surface of the second piezoelectric body 1b can keep an electric field strength applied to the piezoelectric device 1 constant and thus realize an even polarization. Furthermore, the present embodiment of the piezoelectric device 1 is kept from being excessively distorted while the piezoelectric device is used and polarized, thereby protecting the piezoelectric device 1 from being cracked (microcracked).

[Sixth Embodiment]

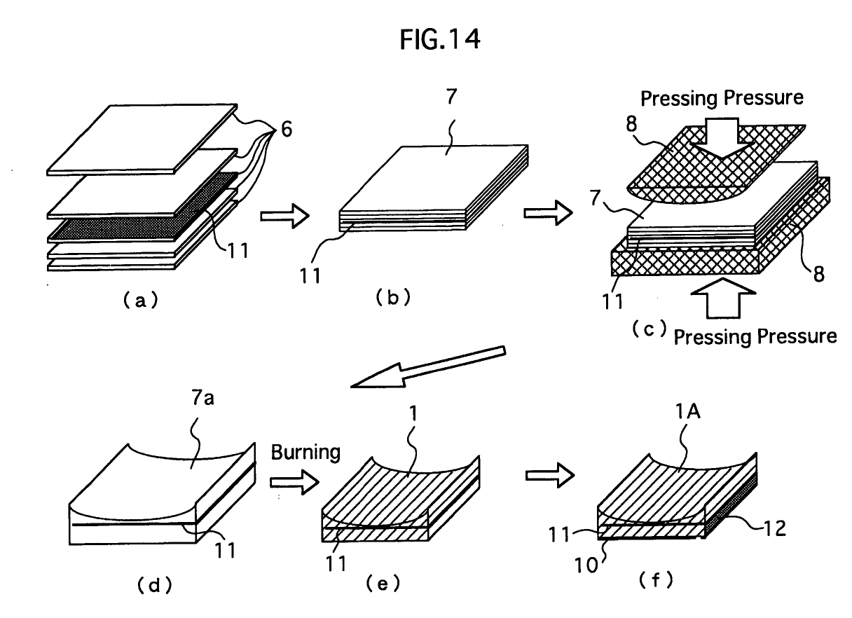

Referring then to FIG. 14 of the drawings, there is shown a sixth preferred embodiment of a method of producing a piezoelectric device 1. The present embodiment of the producing method is different from the fifth embodiment of the producing method in the fact that at least one piece of internal electrode 11 is intervening between at least two pieces of the raw material elements 6 made of a mixture of a piezoelectric material and a binding agent. The present embodiment of the producing method has additional effects of being capable of producing a piezoelectric device 1 having a predetermined thickness distribution with ease and increased flexibility as well as realizing an even polarization, thereby protecting the piezoelectric device 1 from being cracked (microcracked).

Similar to the fifth embodiment, the present embodiment of the piezoelectric device 1 has a thickness concavely curved in a manner that the thickness of the piezoelectric device 1 gradually increases from a center portion toward end portions along lateral directions. The piezoelectric device 1 further comprises an external electrode 10 formed on a plane bottom surface of the piezoelectric device 1, an internal electrode 11 formed inside of the piezoelectric device 1 and spaced apart from and substantially in parallel relationship to the external electrode 10, and an extension electrode 12 extending from the internal electrode 11 to the bottom surface of the piezoelectric device 1 through a side surface of the piezoelectric device 1.

Similar to the first embodiment of the producing process, in the present embodiment, a process of producing a piezoelectric device 1 comprises: a molding process of molding raw materials such as for example piezoelectric ceramic powders to form a plurality of sheet-like raw material elements 6 (not shown in FIG. 14), a laminating process of laminating a plurality of sheet-like raw material elements 6 (including at least one piece of an internal electrode 11) to form a piezoelectric element 7 (shown in FIGS. 14(a) and 14(b)), a pressing process of imparting pressing forces to the piezoelectric element 7 in vertical pressing directions using a die 8 to have the piezoelectric element 7 molded into a predetermined shape to produce a piezoelectric element 7a (shown in FIG. 14(c)), a burning process of burning the piezoelectric element 7a to produce a piezoelectric device 1 (shown in FIGS. 14(d) and 14(e)), and an electrode forming process of forming an external electrode 10 and an extension electrode 12 for the piezoelectric device 1 thus produced (shown in FIG. 14(f)).

As shown in FIG. 14, the raw material elements 6, made of a piezoelectric material, a binding agent, and the like, are flexible and capable of being deformed when pressing forces are imparted to the raw material elements 6, as described hereinearlier. The die 8 is made of a metal material such as for example iron and/or the like, and has a predetermined shape so that the shape of the die 8 is transferred to the piezoelectric element 7. In the pressing process, the die 8 is used to impart pressing forces to the piezoelectric element 7 to have the piezoelectric element 7 molded into a piezoelectric element 7a having a predetermined uneven thickness distribution. The shape of the die 8 is designed so that the piezoelectric element 7 is molded to form a piezoelectric device 1 having a predetermined uneven thickness distribution in view of a shrinkage caused by the burning process.

In the molding process, raw materials including piezoelectric ceramic powders such as for example PZT powders are mixed with a binding agent (including a plasticizer, if required) and immersed in a solvent. A plurality of raw material elements are then extracted from the solvent by way of, for example, a Doctor Blade technique to form a plurality of sheet-like raw material elements 6 each having a thickness in a range of a few ten microns to a few hundred microns.

In the laminating process, one or more sheet-like raw material elements 6 are laminated to form a piezoelectric element 7. Similar to the first embodiment of the producing process, the number and the thicknesses of sheet-like raw material elements 6 to be laminated are calculated in accordance with the thickness distribution of the piezoelectric device 1 in view of a shrinkage caused by the burning process so as to obtain a piezoelectric device 1 having a predetermined thickness distribution after the burning process. On a surface of the sheet-like raw material element 6, an internal electrode 11 made of an electrode material such as, for example, platinum paste capable of resisting high temperatures during the burning process is formed (shown in FIG. 14(a)). The position of the sheet-like raw material element 6 having the internal electrode 11 should be determined so that the internal electrode 11 is placed at a predetermined position of the piezoelectric device 1 with respect to the thickness direction after the burning process. Further, the position and the size of the internal electrode 11 on the surface of the sheet-like raw material element 6 should be determined so that the internal electrode 11 could be electrically connected with a signal wire, not shown in FIG. 14, to receive an electric signal therefrom. In FIG. 14, the internal electrode 11 is placed a little to the right side of the sheet-like raw material element 6 and not protruded from the left side of the sheet-like raw material element 6 so that the internal electrode 11 is connected with the signal wire on the right side of the piezoelectric device 1, and unexpected problem such as a short circuit would not occur on the left side of the piezoelectric device 1.

In the pressing process, a die 8 made of a metal material such as for example aluminum, brass, and/or the like, having a solidity required for the pressing process, and capable of being easily worked, is used to impart pressing forces to the piezoelectric element 7 as shown in FIG. 14(c). In the present embodiment, the die 8 has two vertical pressing surfaces opposing to each other and to be held in pressing contact with the piezoelectric element 7 in vertical directions. Using the die 8, pressing forces are imparted to the piezoelectric element 7 to have the piezoelectric element 7 molded into a piezoelectric element 7a having an uneven thickness distribution concavely curved in a manner that the thickness of the piezoelectric element 7a gradually increases from a center portion toward end portions, and an internal electrode 11 spaced apart from and substantially in parallel relationship to the bottom surface as shown in FIG. 14(d). As will be seen from the foregoing description, the present embodiment of the producing method, in which the die 8 is made of a metal material capable of being molded into a desired shape, and the vertical sides of the piezoelectric element 7 are held in pressing contact with the vertical pressing surfaces of the die 8 while the pressing forces are imparted so that the shape of the die 8 is simply transferred to them can prevent the piezoelectric device 1 from being damaged as well as constantly produce a plurality of piezoelectric devices with high precision.

In the burning process, the piezoelectric element 7a is not processed by any machining means such as for example grinding means, but burned to produce a piezoelectric device 1 having a predetermined uneven thickness distribution. In this manner, a plurality of piezoelectric devices can be constantly produced with high precision because of the fact that the shape of the die 8 is simply transferred to them.

In the electrode forming process, an external electrode 10 made of, for example, baking silver, gold sputter-coated material, and/or the like, is formed on a plane bottom surface of the piezoelectric device 1 after the burning process as shown in FIG. 14(f). Further, an extension electrode 12 is formed for ease in electrical connection with the internal electrode 11. The extension electrode 12 is electrically connected with the internal electrode 11 on the right side surface of the piezoelectric device 1A, and extending therefrom to the bottom surface along the right side surface of the piezoelectric device 1. The extension electrode 12 is made of an electrode material such as, for example, baking silver, gold sputter-coated material, and/or the like, on the piezoelectric device 1 having a desired shape.

Though it has been described in the present embodiment that the piezoelectric device 1A thus produced has a concave surface having a thickness concavely curved in a manner that the thickness of the surface gradually increases from a center portion toward end portions, the same effect can still be obtained even when the surface of the piezoelectric device 1A has an arbitrary shape such as for example a convex surface, convexo-concave surface, or the like, by adaptively modifying the shape of the die 8 in accordance with the desired shape of the surface of the piezoelectric device without restricting the shape of the piezoelectric device 1A.

Furthermore, though it has been described in the present embodiment that the piezoelectric device 1 thus produced is in the form of a quadrilateral sheet shape, the same effect can still be obtained even when the piezoelectric device is in the form of an arbitrary shape such as, for example, a disc sheet shape, by adaptively modifying the shapes of the raw material elements 6 and the die 8 in accordance with the desired shape of the piezoelectric device.

Furthermore, while it has been described in the present embodiment that pressing forces are imparted to the piezoelectric element 7 in vertical pressing directions, the same effect can still be obtained even when pressing forces are imparted to the piezoelectric element 7 in the vertical pressing directions while holding the piezoelectric element 7 with a die wall 9 (shown in FIG. 2) so that the piezoelectric element 7 is prevented from being excessively spread in the directions perpendicular to the pressing directions during the pressing process.

[Seventh Embodiment]

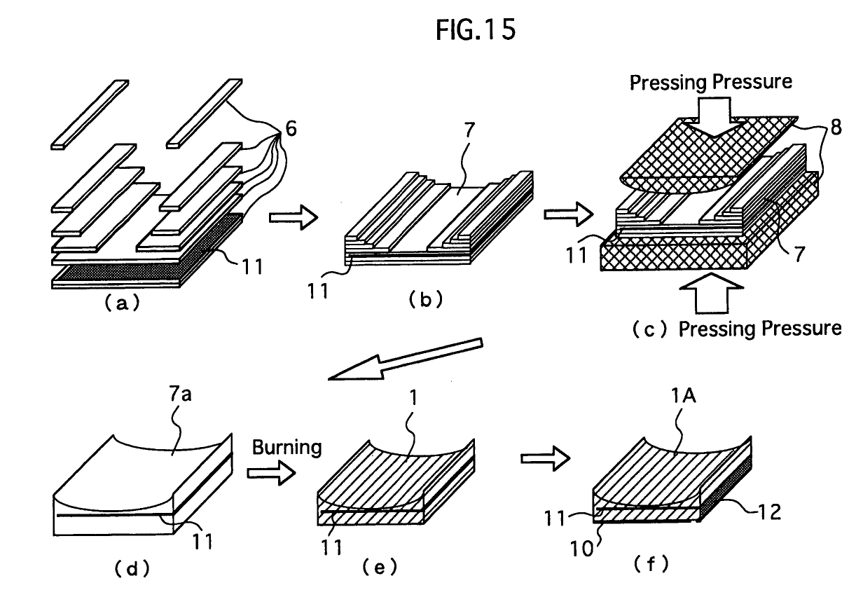

Referring then to FIG. 15 of the drawings, there is shown a seventh preferred embodiment of a method of producing a piezoelectric device 1. The present embodiment of the producing method is different from the sixth embodiment of the producing method in the fact that at least one piece of internal electrode 11 is intervening between at least two pieces of the raw material elements 6 made of a mixture of a piezoelectric material and a binding agent, wherein the raw material elements 6 are laminated in a manner that the number of the laminated raw material elements 6 selectively increases for a thick portion of the piezoelectric device 1A. The present embodiment of the producing method has additional effects of being capable of producing a piezoelectric device 1 having a predetermined thickness distribution with ease and increased flexibility by selectively increasing the number of the raw material elements 6 to be laminated for a thick portion as well as realizing an even polarization, thereby protecting the piezoelectric device 1 from being cracked.

Similar to the fifth embodiment, the present embodiment of the piezoelectric device 1 has a thickness concavely curved in a manner that the thickness of the piezoelectric device 1 gradually increases from a center portion toward end portions along lateral directions. The piezoelectric device 1 further comprises an external electrode 10 formed on a plane bottom surface of the piezoelectric device 1, an internal electrode 11 formed inside of the piezoelectric device 1 and spaced apart from and substantially in parallel relationship to the external electrode 10, and an extension electrode 12 extending from the internal electrode 11 to the bottom surface of the piezoelectric device 1 through a side surface of the piezoelectric device 1.

Similar to the first embodiment of the producing process, in the present embodiment, a process of producing a piezoelectric device 1 comprises: a molding process of molding raw materials such as for example piezoelectric ceramic powders to form a plurality of sheet-like raw material elements 6 (not shown in FIG. 15), a laminating process of laminating a plurality of sheet-like raw material elements 6 (including at least one piece of an internal electrode 11) to form a piezoelectric element 7 (shown in FIGS. 15(a) and 15(b)), a pressing process of imparting pressing forces to the piezoelectric element 7 in vertical pressing directions using a die 8 to have the piezoelectric element 7 molded into a predetermined shape to produce a piezoelectric element 7a (shown in FIG. 15(c)), a burning process of burning the piezoelectric element 7a to produce a piezoelectric device 1 (shown in FIGS. 15(d) and 15(e)), and an electrode forming process of forming an external electrode 10 and an extension electrode 12 for the piezoelectric device 1 thus produced (shown in FIG. 15(f)).

As shown in FIG. 15, the raw material elements 6, made of a piezoelectric material, a binding agent, and the like, are flexible and capable of being deformed when pressing forces are imparted to the raw material elements 6, as described hereinearlier. The die 8 is made of a metal material such as for example iron and/or the like, and has a predetermined shape so that the shape of the die 8 is transferred to the piezoelectric element 7. In the pressing process, the die 8 is used to impart pressing forces to the piezoelectric element 7 to have the piezoelectric element 7 molded into a piezoelectric element 7a having a predetermined uneven thickness distribution. The shape of the die 8 is designed so that the piezoelectric element 7 is molded to form a piezoelectric device 1 having a predetermined uneven thickness distribution in view of a shrinkage caused by the burning process.

In the molding process, raw materials including piezoelectric ceramic powders such as for example PZT powders are mixed with a binding agent (including a plasticizer, if required) and immersed in a solvent. A plurality of raw material elements are then extracted from the solvent by way of, for example, a Doctor Blade technique to form a plurality of sheet-like raw material elements 6 each having a thickness in a range of a few ten microns to a few hundred microns, and a unique width if required.

In the laminating process, one or more sheet-like raw material elements 6 are laminated to form a piezoelectric element 7. Similar to the first embodiment of the producing process, the number and the thicknesses of sheet-like raw material elements 6 to be laminated are calculated in accordance with the thickness distribution of the piezoelectric device 1 in view of a shrinkage caused by the burning process so as to obtain a piezoelectric device 1 having a predetermined thickness distribution after the burning process. In the present embodiment, a plurality of sheet-like raw material elements 6 are laminated in a manner that the widths of the sheet-like raw material elements 6 decreases from a low layer toward a top layer on the both end portions. On a surface of the sheet-like raw material element 6, an internal electrode 11 made of an electrode material such as, for example, platinum paste capable of resisting high temperatures during the burning process is formed (shown in FIG. 15(a)). The position of the sheet-like raw material element 6 having the internal electrode 11 should be determined so that the internal electrode 11 is placed at a predetermined position of the piezoelectric device 1 with respect to the thickness direction after the burning process. Further, the position and the size of the internal electrode 11 on the surface of the sheet-like raw material element 6 should be determined so that the internal electrode 11 could be electrically connected with a signal wire, not shown in FIG. 15, to receive an electric signal therefrom. In FIG. 15, the internal electrode 11 is placed a little to the right side of the sheet-like raw material element 6 and not protruded from the left side of the sheet-like raw material element 6 so that the internal electrode 11 is connected with the signal wire on the right side of the piezoelectric device 1, and unexpected problem such as a short circuit would not occur on the left side of the piezoelectric device 1.

In the pressing process, a die 8 made of a metal material such as for example aluminum, brass, and/or the like, having a solidity required for the pressing process, and capable of being easily worked, is used to impart pressing forces to the piezoelectric element 7 as shown in FIG. 15(c). In the present embodiment, the die 8 has two vertical pressing surfaces opposing to each other and to be held in pressing contact with the piezoelectric element 7 in vertical directions. Using the die 8, pressing forces are imparted to the piezoelectric element 7 to have the piezoelectric element 7 molded into a piezoelectric element 7a having an uneven thickness distribution concavely curved in a manner that the thickness of the piezoelectric element 7a gradually increases from a center portion toward end portions, and an internal electrode 11 spaced apart from and substantially in parallel relationship to the bottom surface as shown in FIG. 15(d). As will be seen from the foregoing description, the present embodiment of the producing method, in which the die 8 is made of a metal material capable of being molded into a desired shape, and the vertical sides of the piezoelectric element 7 are held in pressing contact with the vertical pressing surfaces of the die 8 while the pressing forces are imparted so that the shape of the die 8 is simply transferred to them can prevent the piezoelectric device 1 from being damaged as well as constantly produce a plurality of piezoelectric devices with high precision.

In the burning process, the piezoelectric element 7a is not processed by any machining means such as for example grinding means, but burned to produce a piezoelectric device 1 having a predetermined uneven thickness distribution. In this manner, a plurality of piezoelectric devices can be constantly produced with high precision because of the fact that the shape of the die 8 is simply transferred to them.

In the electrode forming process, an external electrode 10 made of, for example, baking silver, gold sputter-coated material, and/or the like, is formed on a plane bottom surface of the piezoelectric device 1 after the burning process as shown in FIG. 15(f). Further, an extension electrode 12 is formed for ease in electrical connection with the internal electrode 11. The extension electrode 12 is electrically connected with the internal electrode 11 on the right side surface of the piezoelectric device 1A, and extending therefrom to the bottom surface along the right side surface of the piezoelectric device 1A. The extension electrode 12 is made of, for example, baking silver, gold sputter-coated material, and/or the like, on the piezoelectric device 1 having a desired shape.

As will be seen from the foregoing description, it is to be understood that the present embodiment of the producing method can produce a piezoelectric device 1A having a predetermined thickness distribution with ease and increased flexibility by selectively increasing the number of the raw material elements 6 to be laminated for a thick portion.

Though it has been described in the present embodiment that the piezoelectric device 1A thus produced has a concave surface having a thickness concavely curved in a manner that the thickness of the surface gradually increases from a center portion toward end portions, the same effect can still be obtained even when the surface of the piezoelectric device 1A has an arbitrary shape such as for example a convex surface, convexo-concave surface, or the like, by selectively increasing the number of the raw material elements 6 to be laminated for a thick portion without restricting the shape of the piezoelectric device 1A.

Furthermore, though it has been described in the present embodiment that the piezoelectric device 1 thus produced is in the form of a quadrilateral sheet shape, the same effect can still be obtained even when the piezoelectric device is in the form of an arbitrary shape such as, for example, a disc sheet shape, by adaptively modifying the shapes of the raw material elements 6 and the die 8 in accordance with the desired shape of the piezoelectric device.

Furthermore, while it has been described in the present embodiment that a plurality of raw material elements 6 are laminated to produce a piezoelectric device 1 in a manner that the widths of the raw material elements 6 decreases from a low layer toward a top layer on the both end portions, the same effect can still be obtained even when a plurality of raw material elements 6 equal in width or shape to one another are laminated on the both ends to produce a piezoelectric element 7 as shown in FIGS. 16(a) and 16(b). In such a case, a laborious work of carefully laminating the raw material elements 6 in accordance with their widths is eliminated, and the shapes of the raw material elements 6 to be laminated are not restricted by the reason that the number of the raw material elements 6 to be laminated can be selectively increased for a thick portion.

[Eighth Embodiment]

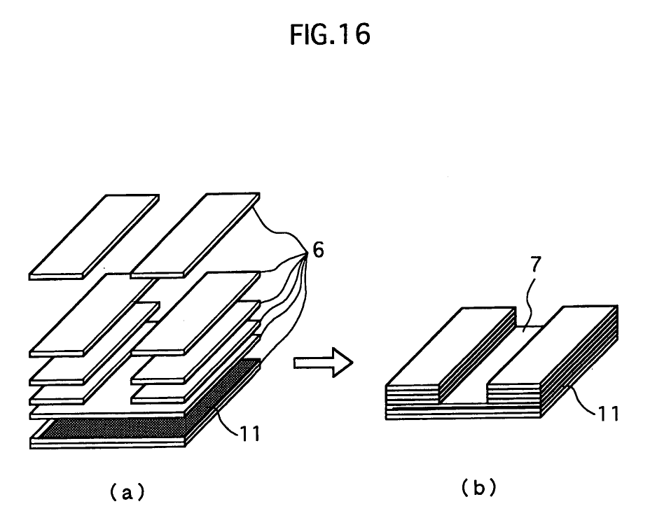

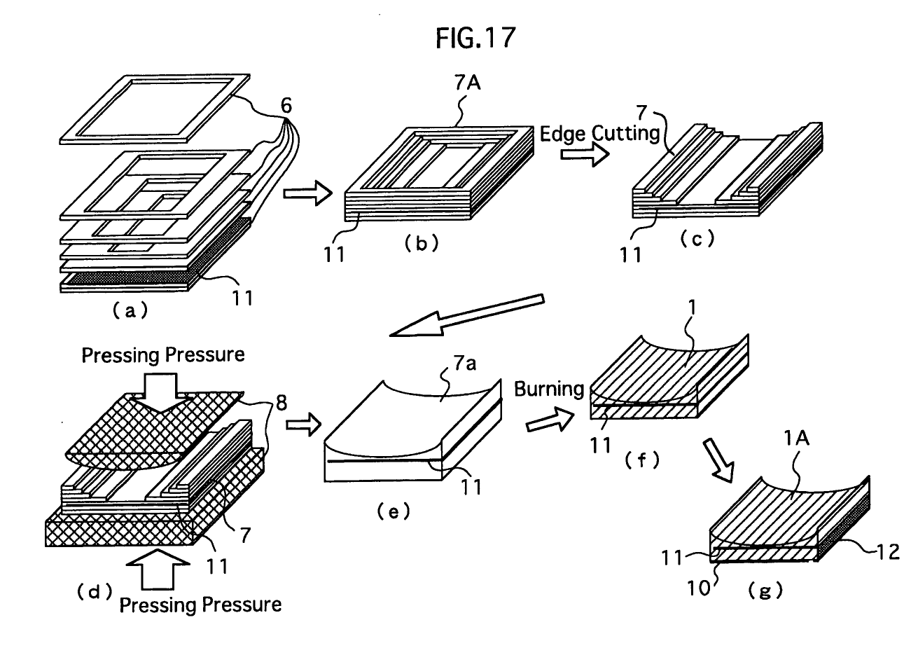

Referring then to FIG. 17 of the drawings, there is shown an eighth preferred embodiment of a method of producing a piezoelectric device 1. The present embodiment of the producing method is different from the seventh embodiment of the producing method in the fact that at least one piece of sheet-like raw material element 6, and two or more pieces of raw material elements 6 respectively formed with through bores different in size to one another are molded, and at least one piece of internal electrode 11 is intervening between at least two pieces of the raw material elements 6 thus molded. The present embodiment of the producing method has additional effects of being capable of producing a piezoelectric device 1 or 1A having predetermined thickness and shape distributions with ease and increased flexibility as well as realizing an even polarization, thereby protecting the piezoelectric device from being cracked.

Similar to the fifth embodiment, the present embodiment of the piezoelectric device 1 has a thickness concavely curved in a manner that the thickness of the piezoelectric device 1 gradually increases from a center portion toward end portions along lateral directions. The piezoelectric device 1 further comprises an external electrode 10 formed on a plane bottom surface of the piezoelectric device 1, an internal electrode 11 formed inside of the piezoelectric device 1 and spaced apart from and substantially in parallel relationship to the external electrode 10, and an extension electrode 12 extending from the internal electrode 11 to the bottom surface of the piezoelectric device 1 through a side surface of the piezoelectric device 1.

Similar to the first embodiment of the producing process, in the present embodiment, a process of producing a piezoelectric device 1 comprises: a molding process of molding raw materials such as for example piezoelectric ceramic powders to form a plurality of sheet-like raw material elements 6 (not shown in FIG. 17), a die-cutting process of die-cutting the sheet-like raw material elements, as many as required, to obtain a plurality of window frame-like raw material elements 6 respectively formed with through bores in the form of rectangular window shapes (not shown in FIG. 17), a laminating process of laminating a plurality of window frame-like raw material elements 6 and a plurality of sheet-like raw material elements 6 ((including at least one piece of an internal electrode 11) to form a piezoelectric element 7A (shown in FIGS. 17(a) and 17(b)), an edge cutting process of cutting off the front end rear edges (unwanted parts) of the piezoelectric element 7A (shown in FIG. 17(c)) to obtain a piezoelectric element 7, a pressing process of imparting pressing forces using a die 8 to the piezoelectric element 7 in vertical pressing directions to have the piezoelectric element 7 molded into a predetermined shape to obtain a piezoelectric element 7a (shown in FIG. 17(d)), a burning process of burning the piezoelectric element 7a (shown in FIGS. 17(e) and 17(f)), and an electrode forming process of forming an external electrode 10 and an extension electrode 12 for the piezoelectric device 1 thus produced (shown in FIG. 17(g)).

As shown in FIG. 17, the raw material elements 6, made of a piezoelectric material, a binding agent, and the like, are flexible and capable of being deformed when pressing forces are imparted to the raw material elements 6, as described hereinearlier. The die 8 is made of a metal material such as for example iron and/or the like, and has a predetermined shape so that the shape of the die 8 is transferred to the piezoelectric element 7. In the pressing process, the die 8 is used to impart pressing forces to the piezoelectric element 7 to have the piezoelectric element 7 molded into a piezoelectric element 7a having a predetermined uneven thickness distribution. The shape of the die 8 is designed so that the piezoelectric element 7 is molded to form a piezoelectric device 1 A having a predetermined uneven thickness distribution in view of a shrinkage caused by the burning process.

In the molding process, raw materials including piezoelectric ceramic powders such as for example PZT powders are mixed with a binding agent (including a plasticizer, if required) and immersed in a solvent. A plurality of raw material elements are then extracted from the solvent by way of, for example, a Doctor Blade technique to form a plurality of sheet-like raw material elements 6 each having a thickness in a range of a few ten microns to a few hundred microns, and a unique width if required.

In the die-cutting process, the sheet-like raw material elements, as many as required, are die-cut to obtain a plurality of window frame-like raw material elements 6 respectively formed with through bores different in shape and size.

In the laminating process, one or more sheet-like raw material elements 6 including window frame-like raw material elements 6 as shown in FIG. 17(a) are laminated to form a piezoelectric element 7A as shown in FIG. 17(b). Here, the number and the thicknesses of sheet-like raw material elements 6 to be laminated are calculated in accordance with the thickness distribution of the piezoelectric device 1 in view of a shrinkage caused by the burning process so as to obtain a piezoelectric device 1 having a predetermined thickness distribution after the burning process. On a surface of one sheet-like raw material element 6, an internal electrode 11 is formed as described hereinearlier. In the present embodiment, the piezoelectric device 1 has a thickness concavely curved in a manner that the thickness of the piezoelectric device 1 gradually increases from a center portion toward end portions along the minor axis. One or more sheet-like raw material elements 6 respectively formed with through-bores are laminated in a manner that the through bores of the one or more sheet-like raw material elements 6 to be laminated should be in size collectively in accordance with the thickness distribution of the piezoelectric device 1. This means that a plurality of window frame-like raw material elements 6 are laminated in a manner that the widths of the window frame-like raw material elements 6 gradually decreases from a low layer toward a top layer on the both end portions to form a piezoelectric element 7A as shown in FIG. 17(b). Similar to the first embodiment of the producing process, while being laminated, the sheet-like raw material elements 6 may be pressed and heated if required.

Preferably, the raw material elements 6 may be made in a manner that the outer edges of the raw material elements 6 are equal in shape (size) to one another so that the raw material elements 6 can be easily laminated without displacements simply after positioning the sheet-like raw material elements 6 with respect to their respective outer edges. Alternatively, each of the raw material elements 6 may have at least one perpendicular edge in a manner that the raw material elements 6 have through bores accurately die-cut with respect to their perpendicular edges so that the raw material elements 6 can be easily laminated without displacements simply after positioning the perpendicular edges of the raw material elements 6 although the raw material elements 6 are not equal in shape to one another. Furthermore, the raw material elements 6 may be laminated in a manner that the through bores of the raw material elements 6 in size collectively correspond to the thickness distribution of the piezoelectric device 1 along a width direction (in the present embodiment, the raw material elements 6 are laminated in a manner that the size of each of the through bores of the raw material elements 6 gradually increases along the width direction from the lower layer to the top layer) so as to form the piezoelectric element 7A having a thickness concavely curved in a manner that the thickness of the piezoelectric element 7A gradually increases from a center portion toward end portions along the minor axis.

In the edge cutting process, unwanted parts of the piezoelectric element 7A collectively constituted by the raw material elements 6 are cut off. The unwanted parts of the piezoelectric element 7A may not be cut off but used as reinforcing parts in the case that the piezoelectric element 7A has such an extremely thin portion that the piezoelectric element 7A as a whole would be abnormally curved and fail to lose its shape when the unwanted parts of the piezoelectric element 7A are cut off. In this case, the unwanted parts of the piezoelectric element 7A may be cut off after the pressing process or the burning process.

In the pressing process, similar to the first embodiment of the producing process, a die 8 made of a metal material such as for example iron and/or the like is used to impart pressing forces to the piezoelectric element 7 in thickness directions as shown in FIG. 17(d) to have the piezoelectric element 7 molded into a piezoelectric element 7a having a predetermined uneven thickness distribution as shown in FIG. 17(e). In the present embodiment of the producing method, the pressing forces imparted by the die 8 to the piezoelectric element 7 are restricted to a certain degree, the piezoelectric element 7 is prevented from being unnecessarily and abnormally deformed, and a residual stress remaining in the piezoelectric element 7a is reduced by the reason that the piezoelectric element 7 laminated in the previous laminating process has a shape approximately similar to the thickness distribution of the piezoelectric device 1 as shown in FIG. 17(c). Furthermore, the present embodiment of the producing method can advantageously produce a piezoelectric device whose thickness distribution is so large (the difference between its thin portion and thick portion is extremely large) that the thickness distribution cannot be formed by simply deforming the piezoelectric element 7.

In the burning process, similar to the first embodiment of the producing process, the piezoelectric element 7a is not processed by any machining means such as for example grinding means, but burned to produce a piezoelectric device 1 having a predetermined uneven thickness distribution. In this manner, a plurality of piezoelectric devices can be constantly produced with high precision because of the fact that the shape of the die 8 is simply transferred to them.

In the electrode forming process, an external electrode 10 made of, for example, baking silver, gold sputter-coated material, and/or the like, is formed on a plane bottom surface of the piezoelectric device 1 after the burning process. Further, an extension electrode 12 is formed for ease in electrical connection with the internal electrode 11. The extension electrode 12 is electrically connected with the internal electrode 11 on the right side surface of the piezoelectric device 1A, and extending therefrom to the bottom surface along the side surface of the piezoelectric device 1A. The extension electrode 12 is made of, for example, baking silver, gold sputter-coated material, and/or the like, on the piezoelectric device 1 having a desired shape.

Though it has been described in the present embodiment that the piezoelectric device 1 thus produced has a concave surface having a thickness concavely curved in a manner that the thickness of the surface gradually increases from a center portion toward end portions, the same effect can still be obtained even when the surface of the piezoelectric device has an arbitrary shape such as for example a convex surface, convexo-concave surface, or the like, by selectively increasing the number of the raw material elements 6 to be laminated for a thick portion 1 in view of the positions, the sizes, and the number of their through bores without restricting the shape of the piezoelectric device.

Furthermore, though it has been described in the present embodiment that the unwanted parts of the piezoelectric element 7A are cut off by the reason that the piezoelectric device 1 thus produced should have a concave surface having a thickness concavely curved in a manner that the thickness of the surface gradually increases from a center portion toward end portions (two directions), the same effect can still be obtained even when the piezoelectric device 1 thus produced has a concave surface having a thickness concavely curved in a manner that the thickness of the surface gradually increases from a center portion toward end portions as shown in FIGS. 6 and 7. In such a case, the piezoelectric element 7A has no unwanted parts to be cut off, and the edge cutting process is accordingly eliminated.

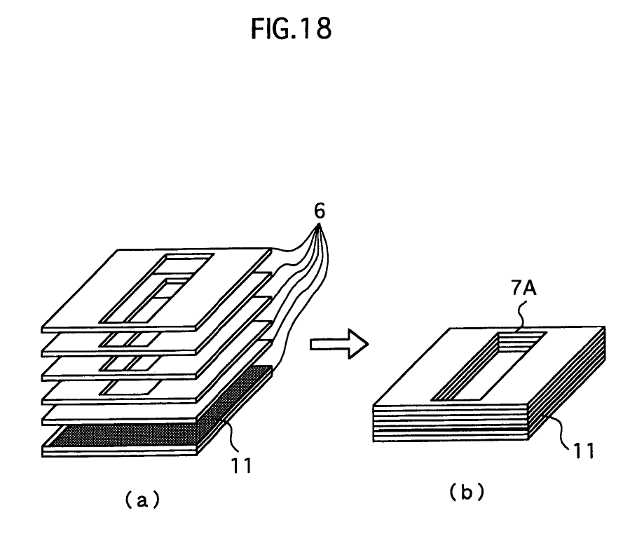

Furthermore, while it has been described in the present embodiment that a plurality of raw material elements 6 are laminated to obtain a piezoelectric element 7A similar in shape to the piezoelectric device 1 to be produced in a manner that the widths of through bores of the raw material elements 6 increases from a low layer toward a top layer, the same effect can still be obtained even when a plurality of raw material elements 6 respectively having through bores equal in width or shape to one another as shown in FIG. 18(a) are laminated to produce a piezoelectric element 7A as shown in FIG. 18(b) as long as the piezoelectric element 7A is similar in shape to the piezoelectric device 1 or 1A to be produced, and the number of the raw material elements 6 to be laminated is selectively increased for a thick portion in view of the positions, the sizes, and the number of their through bores. In such a case, a laborious work of selectively laminating the raw material elements 6 in accordance with the widths of their through bores is eliminated without restricting the shape of the piezoelectric device 1.

Though it has been described in the previous embodiments (shown in FIG. 12 through 18) that the piezoelectric device comprises an extension electrode 12 extending from the internal electrode 11 to the bottom surface of the piezoelectric device 1 through the side surface of the piezoelectric device, the same effect can still be obtained even when the extension electrode 12 is formed only on the side surface of the piezoelectric device, or the internal electrode 11 protruded from the side surface of the piezoelectric device is directly connected with a signal wire in place of the extension electrode 12 as long as the internal electrode 11 can have an electrical connection with the signal wire without restricting the construction of the piezoelectric device 1 or 1A.

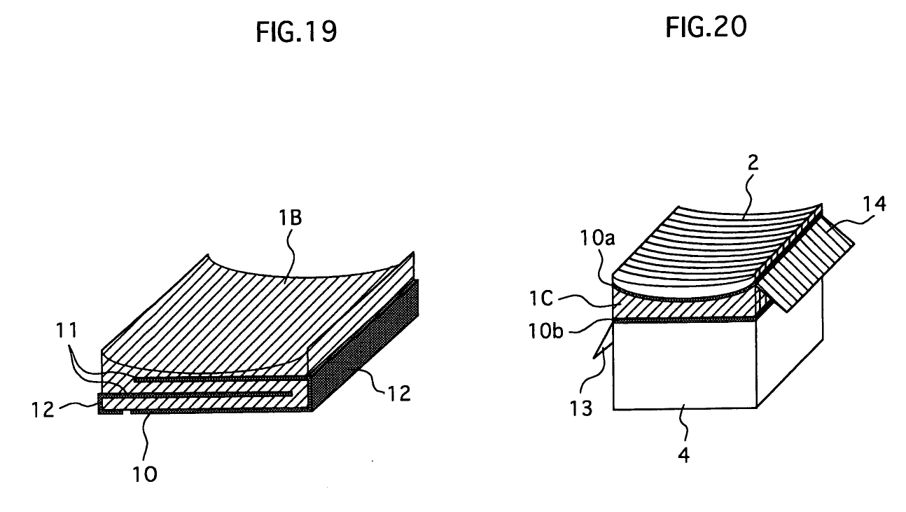

Though it has been described in the previous embodiments (shown in FIG. 12 through 18) that the piezoelectric device comprises an internal electrode 11 of a single layer, the same effect can still be obtained even when the piezoelectric device comprises a plurality of internal electrodes 11 constituted by a plurality of layers each having a predetermined thickness as shown in FIG. 19.

[Ninth Embodiment]

Referring to FIG. 20 of the drawings, there is shown a ninth preferred embodiment of an ultrasonic probe having a piezoelectric device 1C of any one of the first to fourth embodiments according to the present invention.

As shown in FIG. 20, the piezoelectric device 1C further comprises an acoustic matching layer 2 for effectively receiving and transmitting an ultrasonic wave, and a rearward load 4, placed rearward of the piezoelectric device 1C, for carrying out an acoustic damping operation. The piezoelectric device 1C further comprises a signal wire 13 made of, for example, FPC (Flex Print Cables), for electrically connecting an external electrode 10 formed on the bottom surface of the piezoelectric device 1C with an apparatus such as, for example, an ultrasonic diagnostic apparatus, a nondestructive testing apparatus, or the like through a cable, not shown. The piezoelectric device 1C further comprises a ground wire 14 for electrically connecting an external electrode 10 formed on the upper surface of the piezoelectric device 1C with an apparatus such as, for example, an ultrasonic diagnostic apparatus, a nondestructive testing apparatus, or the like through a cable, not shown.

As will be seen from the foregoing description, it is to be understood that the ninth embodiment of the ultrasonic probe according to the present invention, comprising a piezoelectric device 1 as described in any one of the first through fourth embodiments can reliably operate without being influenced by differences among piezoelectric devices. This means that the present embodiment of the ultrasonic probe, comprising a piezoelectric device 1C, which has been produced not by carrying out any technically-difficult machining processing but by simply transferring the shape of the die thereto can protect the piezoelectric device from being microcracked, and ensure that the ultrasonic probe stably maintains its performances. The producing method of any one of the first through fourth embodiments is appropriate for constantly producing a plurality of piezoelectric devices with high precision because of the fact that the shape of the die 8 is simply transferred to them. This leads to the fact that the present embodiment of the ultrasonic probe can reliably operate without being influenced by differences among piezoelectric devices.

Though it has been described in the present embodiment that the piezoelectric device 1C comprises an acoustic matching layer 2 of a single layer, the same effect can still be obtained even when the acoustic matching layer 2 is constituted by a plurality of layers.

Though it has been described in the present embodiment that the signal wire 13 is electrically connected with an external electrode 10b formed on the bottom surface of the piezoelectric device 1C, and the ground wire 14 is electrically connected with an external electrode 10a formed on the upper surface of the piezoelectric device 1C, the same effect can still be obtained even when the signal wire 13 is electrically connected with the external electrode 10a formed on the upper surface of the piezoelectric device 1C, and the ground wire 14 is electrically connected with the external electrode 10b formed on the bottom surface of the piezoelectric device 1C.

Furthermore, through it has been described in the present embodiment that the ultrasonic probe comprises no acoustic lens 3 described in the prior art (shown in FIG. 24), the same effect can still be obtained even when the ultrasonic probe comprises an acoustic lens 3.

[Tenth Embodiment]

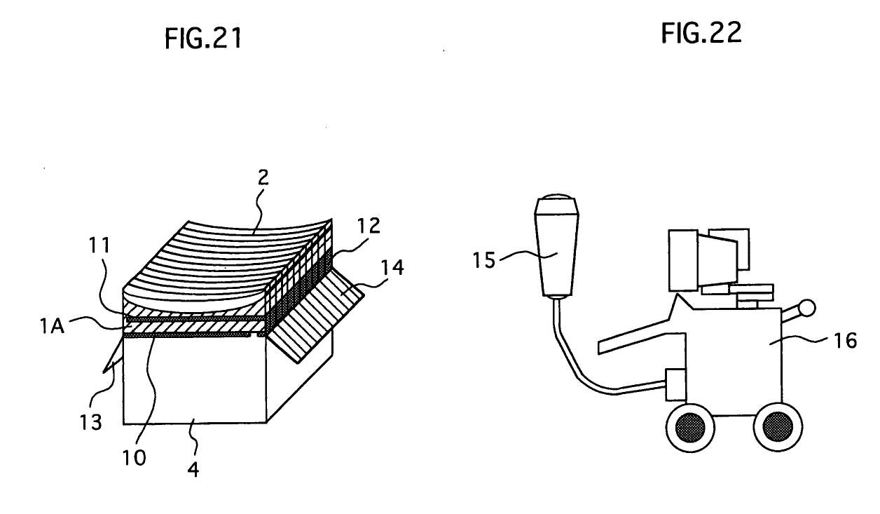

Referring to FIG. 21 of the drawings, there is shown a tenth preferred embodiment of an ultrasonic probe. The present embodiment of the ultrasonic probe is different from the ninth embodiment of the ultrasonic probe in the fact that the ultrasonic probe comprises a piezoelectric device 1A of any one of the fifth to eighth embodiments according to the present invention. The ultrasonic probe thus constructed can stably transmit and receive ultrasonic waves, protect the piezoelectric device 1A from being microcracked, and ensure that the ultrasonic probe maintains its performances by the reason that the piezoelectric device 1A is kept from being excessively distorted while the piezoelectric device is driven. The same constitutional elements are simply represented by the same reference numerals as those of the ninth embodiment, and will be thus omitted from the following description.

As shown in FIG. 21, the ground wire 14 is electrically connected with an extension electrode 12 on the bottom surface of the piezoelectric device 1A. The extension electrode 12 is electrically connected with the internal electrode 11 of the piezoelectric device 1A. The external electrode 10 and the internal electrode 11 are spaced apart from and substantially in parallel relationship with each other. The present embodiment of the piezoelectric device 1A thus constructed is designed to be evenly polarized.

Though it has been described in the present embodiment that the piezoelectric device comprises an acoustic matching layer 2 constituted by a single layer, the same effect can still be obtained even when the acoustic matching layer 2 is constituted by a plurality of layers.

Though it has been described in the present embodiment that the signal wire 13 is electrically connected with an external electrode 10 formed on the bottom surface of the piezoelectric device 1A, and the ground wire 14 is electrically connected with an internal electrode 11 upwardly spaced apart from the external electrode 10, the same effect can still be obtained even when the signal wire 13 is electrically connected with the internal electrode 11, and the ground wire 14 is electrically connected with the external electrode 10.

Furthermore, through it has been described in the present embodiment that the ultrasonic probe comprises no acoustic lens 3 described in the prior art (shown in FIG. 24), the same effect can still be obtained even when the ultrasonic probe comprises an acoustic lens 3.

[Eleventh Embodiment]

Referring to FIG. 22 of the drawings, there is shown an eleventh preferred embodiment of an ultrasonic diagnostic apparatus 16 according to the present invention, comprising an ultrasonic probe 15 of any one of the ninth embodiment (shown in FIG. 20) and tenth embodiment (shown in FIG. 21) according to the present invention. The ultrasonic probe 15 is electrically connected with a main body of the ultrasonic diagnostic apparatus 16 through a cable. The ultrasonic probe of any one of the ninth and tenth embodiments has an advantage of stably operating without being influenced by differences among piezoelectric devices as described hereinearlier.

As will be seen from the foregoing description, it is to be understood that the present embodiment of the ultrasonic diagnostic apparatus 16 according to the present invention, comprising an ultrasonic probe 15 of any one of the ninth embodiment and tenth embodiment can carry out an ultrasound diagnosis with high reliability, taking the advantage of the ultrasonic probe 15.

Though it has been described in the present embodiment that the ultrasonic probe 15 is electrically connected with a main body of the ultrasonic diagnostic apparatus 16 through a cable, the same effect can still be obtained even when the ultrasonic probe 15 is remotely controlled by the main body of the ultrasonic diagnostic apparatus 16 without wires.

[Twelfth Embodiment]

Referring to FIG. 23 of the drawings, there is shown an twelfth preferred embodiment of a nondestructive testing apparatus 17 according to the present invention, comprising an ultrasonic probe 15 of any one of the ninth embodiment (shown in FIG. 20) and tenth embodiment (shown in FIG. 21) according to the present invention. The ultrasonic probe 15 is electrically connected with a main body of the nondestructive testing apparatus 17 through a cable. The ultrasonic probe of any one of ninth and tenth embodiments has an advantage of stably operating without being influenced by differences among piezoelectric devices as described hereinearlier.

As will be seen from the foregoing description, it is to be understood that the present embodiment of the nondestructive testing apparatus 17 according to the present invention, comprising an ultrasonic probe 15 of any one of the ninth embodiment and tenth embodiment can stably carry out a nondestructive test with high reliability, taking the advantage of the ultrasonic probe 15.

Though it has been described in the present embodiment that the ultrasonic probe 15 is electrically connected with a main body of the nondestructive testing apparatus 17 through a cable, the same effect can still be obtained even when the ultrasonic probe 15 is remotely controlled by the main body of the nondestructive testing apparatus 17 without wires.

From the foregoing description, it is to be understood that the piezoelectric device according to the present invention, produced through the processes of mixing a piezoelectric material with a binding agent to form a plurality of raw material elements, and imparting pressing forces to piezoelectric element 7 constituted by the laminated raw material elements to have the piezoelectric element 7 molded into a predetermined shape, has a predetermined thickness distribution and is accurate in dimension. Furthermore, the method of producing a piezoelectric device according to the present invention, comprising the steps of mixing a piezoelectric material with a binding agent to form a plurality of raw material elements, imparting pressing forces to piezoelectric element 7 constituted by the laminated raw material elements to have the piezoelectric element 7 molded into a predetermined shape can produce a plurality of piezoelectric devices each having a thickness distribution with high precision, thereby eliminating the need of carrying out any complicated machining processing such as for example a grinding processing.

1. (Deleted)

2. A method of producing a piezoelectric device, comprising the steps of:
(a) molding one or more raw material elements including at least one piezoelectric material to form a predetermined piezoelectric element; and
(b) imparting pressing forces to said piezoelectric element to have said piezoelectric element molded into a predetermined shape, and in which
said step (a) has a step of laminating a plurality of sheet-like raw material elements respectively having thicknesses collectively in accordance with a thickness distribution of said piezoelectric device.

3. A method of producing a piezoelectric device as set forth in claim 2, in which
said step (a) has a step of laminating the number of sheet-like raw material elements in accordance with a thickness distribution of said piezoelectric device.

4. A method of producing a piezoelectric device as set forth in claim 2, in which
said step (a) has a step of laminating one or more sheet-like raw material elements respectively having shapes collectively in accordance with a thickness distribution of said piezoelectric device.

5. A method of producing a piezoelectric device as set forth in claim 4, in which
said step (a) has a step of laminating one or more sheet-like raw material elements respectively having widths collectively in accordance with a thickness distribution of said piezoelectric device.

6. A method of producing a piezoelectric device as set forth in claim 2, in which
said step (a) has a step of laminating one or more sheet-like raw material elements respectively formed with through bores.

7. A method of producing a piezoelectric device as set forth in claim 6, in which
said step (a) has a step of laminating one or more sheet-like raw material elements respectively formed with through bores in size collectively in accordance with a thickness distribution of said piezoelectric device.

8. A method of producing a piezoelectric device as set forth in claim 2, in which
said step (b) has a step of imparting pressing forces to said piezoelectric element in laminating directions and directions perpendicular to said laminating directions.

9. A method of producing a piezoelectric device, comprising the steps of:
(c) producing a first piezoelectric body having a non-plane first surface and a plane second surface opposite to said first surface, and a second piezoelectric body having a plane first surface and a plane second surface opposite to said first surface, said second piezoelectric body having electrodes respectively on said first and second surfaces; and
(d) fixedly connecting said first piezoelectric body to said second piezoelectric body with said second surface of said first piezoelectric body held in contact with said first surface of said second piezoelectric body.

10. (Deleted)

11. A piezoelectric device, comprising a piezoelectric element having one or more raw material elements including a piezoelectric material, in which pressing forces have been imparted to said piezoelectric element to have said piezoelectric element molded, and
said piezoelectric element having a plurality of sheet-like raw material elements respectively having thicknesses and laminated in accordance with a thickness distribution of said piezoelectric device.

12. A piezoelectric device as set forth in claim 11, in which
said piezoelectric element has a plurality of sheet-like raw material elements respectively formed with through bores, and laminated in accordance with a thickness distribution of said piezoelectric device.

13. A piezoelectric device as set forth in claim 11, in which
said piezoelectric element has a sheet-like raw material element formed with a through bore in size in accordance with a thickness distribution of said piezoelectric device.

14. A piezoelectric device as set forth in claim 11, in which
said piezoelectric element has a plurality of laminated sheet-like raw material elements and a plurality of electrodes spaced apart from one another at a predetermined distance.

15. An ultrasonic probe having a piezoelectric device as set forth in claim 11.

16. An ultrasonic diagnostic apparatus having an ultrasonic probe as set forth in claim 15.

17. A nondestructive testing apparatus having an ultrasonic probe as set forth in claim 15.
